(19) United States
(12) Patent Application Publication
(10) Pub. No.: US 2023/0395617 A1
(43) Pub. Date: Dec. 7, 2023

(54) SOLID-STATE IMAGING DEVICE

(71) Applicant: SONY SEMICONDUCTOR SOLUTIONS CORPORATION, Kanagawa (JP)

(72) Inventors: Mikinori ITO, Kanagawa (JP); Natsuko OOTANI, Kanagawa (JP); Yutaro KOMURO, Kanagawa (JP); Akira OKADA, Kumamoto (JP); Yuhei AOTANI, Kanagawa (JP); Yuichi YAMAGUCHI, Kanagawa (JP); Tsubasa SAKAKI, Kanagawa (JP); Masumi ABE, Kanagawa (JP); Kodai KANEYASU, Kanagawa (JP); Yuta NOGUCHI, Kanagawa (JP); Kazuki TAKAHASHI, Kanagawa (JP); Hirofumi YAMADA, Kanagawa (JP); Kohei YAMASHINA, Kanagawa (JP); Ryosuke TAKAHASHI, Kanagawa (JP); Yoshiki SAITO, Kanagawa (JP); Yusuke KIKUCHI, Kanagawa (JP); Yukihito IIDA, Kanagawa (JP); Kenichi OBATA, Kanagawa (JP); Ryuichi ITOH, Kanagawa (JP); Yuki UEMURA, Kanagawa (JP)

(73) Assignee: SONY SEMICONDUCTOR SOLUTIONS CORPORATION, Kanagawa (JP)

(21) Appl. No.: 18/248,732

(22) PCT Filed: Oct. 19, 2021
(86) PCT No.: PCT/JP2021/038657

§ 371 Date: Apr. 12, 2023

(30) Foreign Application Priority Data
Oct. 20, 2020 (JP) 2020-176278
Feb. 4, 2021 (JP) 2021-016898

(51) Int. Cl. H01L 27/146

(52) U.S. Cl. CPC H01L 27/14603; H01L 27/14645; H01L 27/1463; H01L 27/14636; H01L 27/1464; H01L 27/14689; H04N 25/78

(57) ABSTRACT

There is provided a solid-state imaging device capable of preventing the sensitivity difference from being generated between the pixels.

The fixed imaging device of the present disclosure includes: a first pixel; and a second pixel located in a first direction of the first pixel, in which each of the first and second pixels includes a first transistor and a second transistor, and the first and second transistors in the second pixel are disposed periodically in the first direction with respect to the first and second transistors in the first pixel.

### TECHNICAL FIELD

The present disclosure relates to a solid-state imaging device.

### BACKGROUND ART

The solid-state imaging device includes, for example, a plurality of pixels arranged in a two-dimensional array, and an element isolation insulation film surrounding each of the pixels. Each of the pixels includes, for example, a pixel transistor such as a transfer transistor, a reset transistor, a selection transistor, or an amplification transistor, or a dummy transistor that is a dummy of the pixel transistor.

### CITATION LIST

### Patent Document

Patent Document 1: WO 2017/130723 A
Patent Document 2: Japanese Patent Application Laid-Open No. 2015-162679
Patent Document 3: US 2020/0111821 A
Patent Document 4: US 2017/0092684 A

### SUMMARY OF THE INVENTION

### Problems to be Solved by the Invention

However, depending on the arrangement of the pixels and the shape of the element isolation insulation film, a sensitivity difference may be generated between the pixels of the solid-state imaging device.

Therefore, the present disclosure provides a solid-state imaging device capable of preventing the sensitivity difference from being generated between the pixels.

### Solutions to Problems

According to a first aspect of the present disclosure, there is provided a fixed imaging device including: a first pixel; and a second pixel located in a first direction of the first pixel, in which each of the first and second pixels includes a first transistor and a second transistor, and the first and second transistors in the second pixel are disposed periodically in the first direction with respect to the first and second transistors in the first pixel. In this configuration, for example, it is possible to prevent a sensitivity difference from being generated between the first pixel and the second pixel.

Furthermore, the solid-state imaging device according to the first aspect may further includes: a third pixel located in a second direction of the first pixel; and a fourth pixel located in the second direction of the second pixel, in which each of the third and fourth pixels may include the first transistor and the second transistor, and the first and second transistors in the fourth pixel may be disposed periodically in the first direction with respect to the first and second transistors in the third pixel. In this configuration, for example, it is possible to prevent a sensitivity difference from being generated between the first pixel and the second pixel, and between the third pixel and the fourth pixel.

Furthermore, according to the first aspect, the first and second transistors in the third pixel may be disposed symmetrically in the second direction with respect to the first and second transistors in the first pixel, and/or the first and second transistors in the fourth pixel may be disposed symmetrically in the second direction with respect to the first and second transistors in the second pixel. In this configuration, for example, it is possible to prevent a sensitivity difference from being generated between the first pixel and the second pixel, and between the third pixel and the fourth pixel.

Furthermore, according to the first aspect, the first and second transistors in the third pixel may be disposed periodically in the second direction with respect to the first and second transistors in the first pixel, and/or the first and second transistors in the fourth pixel may be disposed periodically in the second direction with respect to the first and second transistors in the second pixel. In this configuration, for example, it is possible to prevent a sensitivity difference from being generated between the first pixel and the third pixel, and/or between the second pixel and the fourth pixel.

Furthermore, according to the first aspect, each of the first and second pixels may include a photoelectric conversion unit provided in a substrate, and include the first and second transistors under the substrate. In this configuration, for example, it is possible to prevent a sensitivity difference from being generated between the pixels including the photoelectric conversion unit.

Furthermore, according to the first aspect, the photoelectric conversion unit may include a first semiconductor region and a second semiconductor region surrounding the first semiconductor region, and the first and second semiconductor regions in the second pixel may be disposed periodically in the first direction with respect to the first and second semiconductor regions in the first pixel. In this configuration, for example, it is possible to prevent a sensitivity difference from being generated between the pixels, which is caused by the photoelectric conversion unit.

Furthermore, according to the first aspect, each of the first and second pixels may include a floating diffusion portion in the substrate, and the floating diffusion portion in the second pixel may be disposed periodically in the first direction with respect to the floating diffusion portion in the first pixel. In this configuration, for example, it is possible to prevent a sensitivity difference from being generated between the pixels, which is caused by the floating diffusion portion.

Furthermore, the solid-state imaging device according to the first aspect may further include a first wiring layer provided under the substrate and including a plurality of first wirings, in which the first wirings in the second pixel may be disposed periodically in the first direction with respect to the first wirings in the first pixel. In this configuration, for example, it is possible to prevent a sensitivity difference from being generated between the pixels, which is caused by the first wiring layer.

Furthermore, according to the first aspect, each of the first and second pixels may include the plurality of first wirings extending to one side in the first direction or second direction. In this configuration, for example, the first wirings can be suitably disposed.

Furthermore, the solid-state imaging device according to the first aspect may further include a second wiring layer provided under the first wiring layer and including a plurality of second wirings, in which the second wirings in the second pixel may be disposed periodically in the first direction with respect to the second wirings in the first pixel. In this configuration, for example, it is possible to prevent a sensitivity difference from being generated between the pixels, which is caused by the second wiring layer.

Furthermore, according to the first aspect, each of the first and second pixels may include the plurality of first wirings extending to one side in the first direction or second direction and the plurality of second wirings extending to the other side in the first direction or second direction. In this configuration, for example, the first and second wirings can be suitably disposed.

Furthermore, according to the first aspect, the first transistor may be a transfer transistor. In this configuration, for example, it is possible to prevent a sensitivity difference from being generated between the pixels, which is caused by the transfer transistor.

Furthermore, according to the first aspect, the second transistor may be a pixel transistor other than the transfer transistor or a dummy transistor that is a dummy of the pixel transistor. In this configuration, for example, it is possible to prevent a sensitivity difference from being generated between the pixels, which is caused by the pixel transistor or the dummy transistor other than the transfer transistor.

Furthermore, according to the first aspect, at least one of the first pixel or the second pixel may not include an element isolation insulation film between the first transistor and the second transistor. In this configuration, for example, it is possible to prevent a sensitivity difference from being generated between the pixels, which is caused by the element isolation insulation film.

Furthermore, the solid-state imaging device according to the first aspect may further include an element isolation insulation film surrounding each of the first and second pixels. In this configuration, for example, it is possible to prevent colors from being mixed between the pixels.

According to a second aspect of the present disclosure, there is provided a fixed imaging device including: a first pixel; and a second pixel located in a first direction of the first pixel, in which each of the first and second pixels includes a first transistor and a second transistor, and at least one of the first pixel or the second pixel does not include an element isolation insulation film between the first transistor and the second transistor. In this configuration, for example, it is possible to prevent a sensitivity difference from being generated between the pixels, which is caused by the element isolation insulation film.

Furthermore, the solid-state imaging device according to the second aspect may further include an element isolation insulation film surrounding each of the first and second pixels. In this configuration, for example, it is possible to prevent colors from being mixed between the pixels.

According to a third aspect of the present disclosure, there is provided a fixed imaging device including: a first pixel; a second pixel located adjacent to the first pixel in a first direction; a third pixel located adjacent to the first pixel in a second direction; a fourth pixel located adjacent to the second pixel in the second direction; a first element isolation insulation film provided in each of the first to fourth pixels; and a second element isolation insulation film surrounding each of the first to fourth pixels, in which at least one of the first element isolation insulation film or the second element isolation insulation film includes a portion having a first width and a portion having a second width larger than the first width in plan view. In this configuration, for example, it is possible to prevent a sensitivity difference from being generated among the first to fourth pixels by the first or second element isolation insulation film.

Furthermore, according to third aspect, each of the first to fourth pixels may include a first transistor and a second transistor, the first element isolation insulation film may be disposed between the first transistor and the second transistor, the first transistors in the first to fourth pixels may be disposed periodically in the first and second directions, and the second transistors in the first to fourth pixels may include gate electrodes having two or more types of areas in plan view. In this configuration, for example, it is possible to prevent a sensitivity difference caused by the second transistor.

Furthermore, according to the third aspect, each of the first to fourth pixels may include a first transistor and a second transistor, the first element isolation insulation film may be disposed between the first transistor and the second transistor, the first transistors in the first to fourth pixels may be disposed periodically in the first and second directions, and the second transistors in the first to fourth pixels may be disposed periodically in the first and the second directions. In this configuration, for example, it is possible to prevent a sensitivity difference caused by the transistor other than the second transistor.

### BRIEF DESCRIPTION OF DRAWINGS

FIG. 1 is a block diagram illustrating a configuration of a solid-state imaging device according to a first embodiment.

FIG. 2 is a cross-sectional view illustrating a structure of a solid-state imaging device according to the first embodiment.

FIG. 3 is another cross-sectional view illustrating a structure of a solid-state imaging device according to the first embodiment.

FIG. 4 illustrates a plan view and a cross-sectional view of a structure of a solid-state imaging device according to the first embodiment.

FIG. 5 illustrates a plan view and a cross-sectional view of a structure of a solid-state imaging device according to a comparative example of the first embodiment.

FIG. 6 is a plan view schematically illustrating an example of a wiring layer according to the first embodiment.

FIG. 7 is a cross-sectional view (1/6) illustrating a manufacturing method for a solid-state imaging device according to the first embodiment.

FIG. 8 is a cross-sectional view (2/6) illustrating a manufacturing method for a solid-state imaging device according to the first embodiment.

FIG. 9 is a cross-sectional view (3/6) illustrating a manufacturing method for a solid-state imaging device according to the first embodiment.

FIG. 10 is a cross-sectional view (4/6) illustrating a manufacturing method for a solid-state imaging device according to the first embodiment.

FIG. 11 is a cross-sectional view (5/6) illustrating a manufacturing method for a solid-state imaging device according to the first embodiment.

FIG. 12 is a cross-sectional view (6/6) illustrating a manufacturing method for a solid-state imaging device according to the first embodiment.

FIG. 13 illustrates a plan view and a cross-sectional view of a structure of a solid-state imaging device according to a modification example of the first embodiment.

FIG. 14 is a cross-sectional view illustrating a structure of a solid-state imaging device according to the modification example of the first embodiment.

FIG. 15 is another cross-sectional view illustrating a structure of a solid-state imaging device according to the modification example of the first embodiment.

FIG. 16 illustrates a plan view and a cross-sectional view of a structure of a solid-state imaging device according to a second embodiment.

FIG. 17 illustrates a plan view and a cross-sectional view of a structure of a solid-state imaging device according to a modification example of the second embodiment.

FIG. 18 illustrates a plan view and a cross-sectional view of a structure of a solid-state imaging device according to another modification example of the second embodiment.

FIG. 19 is a plan view illustrating a structure of a solid-state imaging device according to a third embodiment.

FIG. 20 is a cross-sectional view illustrating a structure of a solid-state imaging device according to the third embodiment.

FIG. 21 is a plan view illustrating a structure of a solid-state imaging device according to a first modification example of the third embodiment.

FIG. 22 is a plan view illustrating a structure of a solid-state imaging device according to a second modification example of the third embodiment.

FIG. 23 is a plan view illustrating a structure of a solid-state imaging device according to a third modification example of the third embodiment.

FIG. 24 is a plan view illustrating a structure of a solid-state imaging device according to a fourth modification example of the third embodiment.

FIG. 25 illustrates a plan view and a cross-sectional view of a structure of a solid-state imaging device according to a fourth embodiment.

FIG. 26 illustrates a plan view and a cross-sectional view of a structure of a solid-state imaging device according to a modification example of the fourth embodiment.

FIG. 27 is a cross-sectional view illustrating a structure of a solid-state imaging device according to a fifth embodiment.

FIG. 28 is a cross-sectional view illustrating a structure of a solid-state imaging device according to a modification example of the fifth embodiment.

FIG. 29 is a plan view illustrating a structure of a solid-state imaging device according to a sixth embodiment.

FIG. 30 is a plan view illustrating a structure of a solid-state imaging device according to a modification example of the sixth embodiment.

FIG. 31 is a plan view illustrating a structure of a solid-state imaging device according to another modification example of the sixth embodiment.

FIG. 32 is a plan view illustrating a structure of a solid-state imaging device according to still another modification example of the sixth embodiment.

FIG. 33 illustrates a plan view and a cross-sectional view of a structure of a solid-state imaging device according to a seventh embodiment.

FIG. 34 illustrates a plan view and a cross-sectional view of a structure of a solid-state imaging device according to an eighth embodiment.

FIG. 35 illustrates a plan view and a cross-sectional view of a structure of a solid-state imaging device according to a comparative example of the eighth embodiment.

FIG. 36 is a plan view illustrating a structure of a solid-state imaging device according to a ninth embodiment.

FIG. 37 is a plan view illustrating a structure of a solid-state imaging device according to a modification example of the ninth embodiment.

FIG. 38 is a block diagram illustrating a configuration example of an electronic apparatus.

FIG. 39 is a block diagram illustrating a configuration example of a mobile body control system.

FIG. 40 is a plan view illustrating a specific example of a setting position of an imaging unit of FIG. 39.

FIG. 41 is a diagram illustrating an example of a schematic configuration of an endoscopic surgery system.

FIG. 42 is a block diagram illustrating an example of functional configurations of a camera head and a CCU.

### MODE FOR CARRYING OUT THE INVENTION

Hereinafter, embodiments of the present disclosure will be described with reference to the drawings.

### First Embodiment

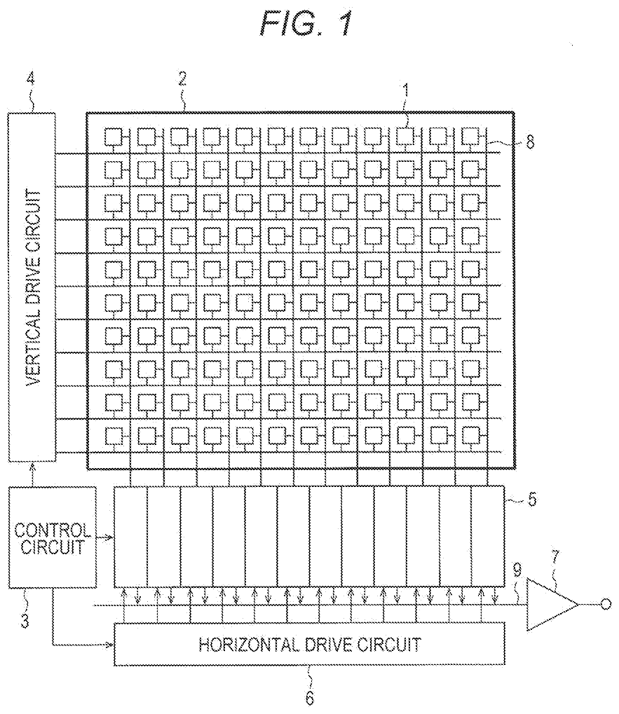

FIG. 1 is a block diagram illustrating a configuration of a solid-state imaging device according to the first embodiment.

The solid-state imaging device in FIG. 1 is a complementary metal oxide semiconductor (CMOS) image sensor, and includes a pixel array region 2 having a plurality of pixels 1, a control circuit 3, a vertical drive circuit 4, a plurality of column signal processing circuits 5, a horizontal drive circuit 6, an output circuit 7, a plurality of vertical signal lines 8, and a horizontal signal line 9.

Each of the pixels 1 includes a photodiode functioning as a photoelectric conversion unit and a MOS transistor functioning as a pixel transistor. Examples of the pixel transistor include a transfer transistor, a reset transistor, a selection transistor, and an amplification transistor. Some pixels 1 include a dummy transistor that is a dummy of the pixel transistor.

The pixel array region 2 includes a plurality of the pixels 1 arranged in a two-dimensional array. The pixel array region 2 includes an effective pixel region that receives light to perform photoelectric conversion, and amplifies and outputs a signal charge generated by the photoelectric conversion, and a black reference pixel region that outputs optical black serving as a reference of a black level. Generally, the black reference pixel region is disposed on an outer peripheral portion of the effective pixel region.

The control circuit 3 generates various signals serving as references of operations of the vertical drive circuit 4, each of the column signal processing circuits 5, the horizontal drive circuit 6, and the like on the basis of a vertical synchronization signal, a horizontal synchronization signal, a master clock, and the like. The signal generated by the control circuit 3 is, for example, a clock signal or a control signal, and is input to the vertical drive circuit 4, the column signal processing circuit 5, the horizontal drive circuit 6, and the like.

The vertical drive circuit 4 includes, for example, a shift register, and scans each of the pixels 1 in the pixel array region 2 in a vertical direction row by row. The vertical drive circuit 4 further supplies a pixel signal based on the signal charge generated by each of the pixels 1 to the column signal processing circuit 5 through each of the vertical signal lines 8.

The column signal processing circuit 5 is disposed, for example, for each column formed by the pixels 1 in the pixel array region 2, and performs signal processing on the signals output from the pixels 1 forming one row for each column on the basis of the signals from the black reference pixel region. Examples of this signal processing include noise removal and signal amplification.

The horizontal drive circuit 6 includes, for example, a shift register, and supplies the pixel signal from each column signal processing circuit 5 to the horizontal signal line 9.

The output circuit 7 performs signal processing on the signal supplied from each column signal processing circuit 5 through the horizontal signal line 9, and outputs the signal subjected to the signal processing.

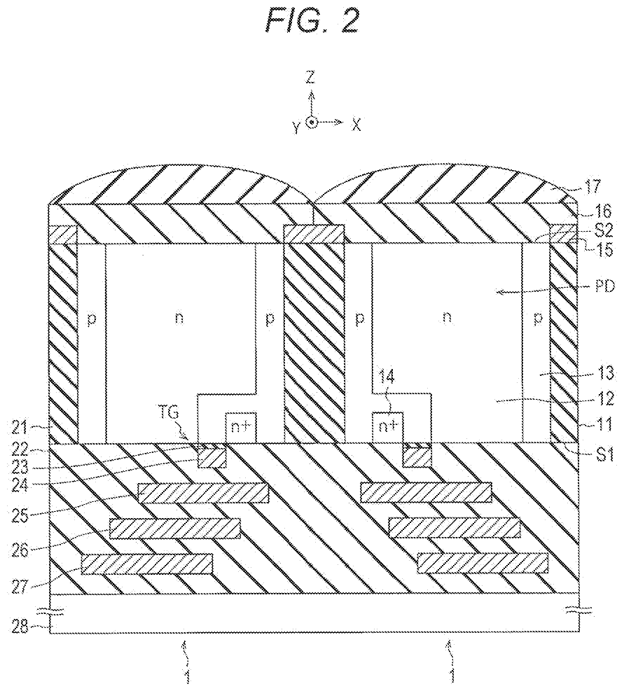

FIG. 2 is a cross-sectional view illustrating a structure of the solid-state imaging device according to the first embodiment. FIG. 2 illustrates a longitudinal cross section of two pixels 1 included in the pixel array region 2.

FIG. 2 illustrates an X-axis, a Y-axis, and a Z-axis, which are perpendicular to each other. An X direction and a Y direction correspond to a transverse direction, and a Z direction corresponds to a longitudinal direction. Furthermore, a +Z direction corresponds to an upward direction, and a −Z direction corresponds to a downward direction. A −Z direction may strictly correspond to a gravity direction, or may not strictly correspond to the gravity direction. The pixel array 2 of the present embodiment includes a plurality of the pixels 1 arranged in a two-dimensional array in the X direction and the Y direction. The Y direction is an example of a first direction of the present disclosure, and the X direction is an example of a second direction of the present disclosure.

As illustrated in FIG. 2, the solid-state imaging device of the present embodiment includes a substrate 11, an n-type semiconductor region 12, p-type semiconductor region 13 and n⁺-type semiconductor region 14 of each pixel 1, a light-shielding film 15, a color filter 16 and on-chip lens 17 of each pixel 1, an element isolation insulation film 21, an interlayer insulation film 22, a gate insulation film 23 and gate electrode 24 of each pixel 1, a wiring layer 25, a wiring layer 26, a wiring layer 27, and a support substrate 28. As illustrated in FIG. 2, the solid-state imaging device of the present embodiment further includes a photodiode PD and transfer transistor TG of each pixel 1.

The substrate 11 is, for example, a semiconductor substrate such as a silicon (Si) substrate. FIG. 2 illustrates a front surface S1 of the substrate 11 and a back surface S2 of the substrate 11. In FIG. 2, the front surface S1 of the substrate 11 is a surface (lower surface) of the substrate 11 in the −Z direction, and the back surface S2 of the substrate 11 is a surface (upper surface) of the substrate 11 in the +Z direction. Since the solid-state imaging device according to the present embodiment is a back-surface irradiation type device, the back surface S2 of the substrate 11 is a light incident surface (light-reception surface) of the substrate 11.

The n-type semiconductor region 12 of each pixel 1 and the p-type semiconductor region 13 of each pixel 1 are provided in the substrate 11 and form a pn junction. The photodiode PD of each pixel 1 is mainly realized by the pn junction. The photodiode PD functions as a photoelectric conversion unit that converts light into an electric charge. Specifically, the photodiode PD receives light through the back surface S2 of the substrate 11, generates a signal charge according to the amount of received light, and accumulates the generated signal charge in the n-type semiconductor region 12. In the present embodiment, the n-type semiconductor region 12 and the p-type semiconductor region 13 generally have a columnar shape and tubular shape extending in the Z direction, and the p-type semiconductor region 13 surrounds the n-type semiconductor region 12 in a tubular shape. The n-type semiconductor region 12 is an example of a first semiconductor region of the present disclosure, and the p-type semiconductor region 13 is an example of a second semiconductor region of the present disclosure.

The n⁺-type semiconductor region 14 of each pixel 1 is provided under the p-type semiconductor region 13 in the substrate 11, and functions as, for example, a floating diffusion portion. The n⁺-type semiconductor region 14 is formed, for example, by implanting an n-type impurity at a high concentration into a part of the p-type semiconductor region 13. In the present embodiment, the signal charge accumulated in the n-type semiconductor region 12 is transferred to the n⁺-type semiconductor region 14.

The light-shielding film 15 is a film having a function of shielding light, and is formed on the back surface S2 of the substrate 11. The light-shielding film 15 of the present embodiment is formed on the element isolation insulation film 21 provided in the substrate 11, and has a mesh-like planar shape. Light incident on the light-shielding film 15 is shielded by the light-shielding film 15 or passes through an opening (mesh) of the light-shielding film 15. The light-shielding film 15 is, for example, a film containing a metal element such as tungsten (W), aluminum (Al), or copper (Cu).

The color filter 16 has a function of transmitting light having a predetermined wavelength, and is formed on the back surface S2 of the substrate 11 for each pixel 1. For example, the color filters 16 for red (R), green (G), and blue (B) are disposed on the photodiodes PD of red, green, and blue pixels 1, respectively. Moreover, the color filter 16 for infrared light may be disposed on the photodiode PD of the pixel 1 of infrared light.

The on-chip lens 17 has a function of condensing incident light, and is formed on the color filter 16 for each pixel 1. The light condensed by the on-chip lens 17 passes through the color filter 16 and enters the photodiode PD. The photodiode PD converts the light into an electric charge.

The element isolation insulation film 21 is provided in the substrate 11 and isolates the pixels 1 of the solid-state imaging device from each other. The element isolation insulation film 21 is provided to prevent colors from being mixed between the pixels 1. The element isolation insulation film 21 of the present embodiment penetrates the substrate 11 from the front surface S1 to the back surface S2. Furthermore, the element isolation insulation film 21 of the present embodiment has a shape surrounding each pixel 1. Therefore, the color mixing between the pixels 1 can be effectively suppressed. The element isolation insulation film 21 is, for example, a silicon oxide (SiO₂) film. The element isolation insulation film 21 may include a film having a negative fixed charge (fixed charge film). Note that the element isolation insulation film 21 of the present embodiment includes a portion penetrating the substrate 11 alone and a portion penetrating the substrate 11 together with an element isolation insulation film 29 to be described later.

The interlayer insulation film 22 is formed on the front surface S1 of the substrate 11. The interlayer insulation film 22 is, for example, a silicon oxide film or a laminated film including the silicon oxide film and other insulation films.

The gate insulation film 23 and gate electrode 24 of each pixel 1 are sequentially provided on the front surface S1 of the substrate 1 and covered by the interlayer insulation film 22. The gate insulation film 23 and gate electrode 24 of the present embodiment are provided under the p-type semiconductor region 13 between the n-type semiconductor region 12 and the n⁺-type semiconductor region 14, and form the transfer transistor TG. The transfer transistor TG can transfer the signal charge accumulated in the n-type semiconductor region 12 to the n⁺-type semiconductor region 14. The transfer transistor TG is an example of a first transistor of the present disclosure.

Note that the transfer transistor TG may be a vertical transistor. That is, the gate insulation film 23 and gate electrode 24 of the transfer transistor TG may include a portion embedded in a groove formed in the substrate 11.

The wiring layers 25 to 27 are sequentially provided in the interlayer insulation film 22 on the front surface S1 of the substrate 11, and form a multilayer wiring structure. The multilayer wiring structure of the present embodiment includes the three wiring layers 25 to 27, but may include four or more wiring layers. Each of the wiring layers 25 to 27 includes a plurality of wirings, and the pixel transistor such as the transfer transistor TG is driven using these wirings. The wiring layers 25 to 27 are, for example, layers containing a metal element such as tungsten, aluminum, or copper. The wiring layers 25 to 27 are examples of first and second wiring layers of the present disclosure.

The support substrate 28 is provided on the front surface S1 of the substrate 11 via the interlayer insulation film 22, and is provided to secure the strength of the substrate 11. The support substrate 28 is, for example, a semiconductor substrate such as a silicon substrate.

In the present embodiment, light incident on the on-chip lens 17 is condensed by the on-chip lens 17, passes through the color filter 16, passes through the opening of the light-shielding film 15, and is incident on the photodiode PD. The photodiode PD converts the light into an electric charge by photoelectric conversion to generate a signal charge. The signal charge is output as a pixel signal via the vertical signal lines 8 in the wiring layers 25 to 27.

Note that the n-type semiconductor region and p-type semiconductor region in the substrate 11 of the present embodiment may be interchanged with each other. Specifically, the n-type semiconductor region 12, the p-type semiconductor region 13, and the n⁺-type semiconductor region 14 may be changed to the p-type semiconductor region, the n-type semiconductor region, and the p⁺-type semiconductor region, respectively.

Next, a relationship between two pixels 1 illustrated in FIG. 2 will be described.

Two pixels 1 illustrated in FIG. 2 are adjacent to each other in the X direction. In the present embodiment, the structures of these pixels 1 are symmetrical in the X direction. Specifically, components corresponding to each other in these pixels 1 have a shape symmetrical in the X direction and are disposed symmetrically in the X direction. The boundary surface between two pixels 1 illustrated in FIG. 2 is located in the element isolation insulation film 21 between these pixels 1, and the structures of these pixels 1 are symmetric with respect to this boundary surface. In other words, the structures of these pixels 1 form a mirror image with respect to the boundary surface.

Each component in the right pixel 1 illustrated in FIG. 2 is disposed symmetrically in the X direction with respect to the corresponding component in the left pixel 1 illustrated in FIG. 2. For example, the gate insulation film 23 and gate electrode 24 of the right transfer transistor TG are respectively disposed symmetrically in the X direction with respect to the gate insulation film 23 and gate electrode 24 of the left transfer transistor TG. Moreover, the n-type semiconductor region 12, p-type semiconductor region 13, and n⁺-type semiconductor region 14 in the right pixel 1 are respectively disposed symmetrically in the X direction with respect to the n-type semiconductor region 12, p-type semiconductor region 13, and n⁺-type semiconductor region 14 in the left pixel 1.

Furthermore, wirings of each of the wiring layers 25 to 27 in the right pixel 1 are disposed symmetrically in the X direction with respect to the corresponding wirings of each of the wiring layers 25 to 27 in the left pixel 1. In FIG. 2, one wiring of the wiring layer 25, one wiring of the wiring layer 26, and one wiring of the wiring layer 27 in the right pixel 1 are disposed symmetrically in the X direction with respect to one wiring of the wiring layer 25, one wiring of the wiring layer 26, and one wiring of the wiring layer 27 in the left pixel 1, respectively. In the present embodiment, other wirings of each of the wiring layers 25 to 27 in the right pixel 1 is also disposed symmetrically in the X direction with respect to the corresponding wirings of each of the wiring layers 25 to 27 in the left pixel 1.

Note that, any of the components corresponding to each other in these pixels 1 may not be disposed symmetrically in the X direction. For example, any wiring of the wiring layers 25 to 27 in the right pixel 1 may not be disposed symmetrically in the X direction with respect to the corresponding wiring of the wiring layers 25 to 27 in the left pixel 1. Furthermore, any wiring of the wiring layers 25 to 27 in the right pixel 1 may not correspond to any wiring of the wiring layers 25 to 27 in the left pixel 1.

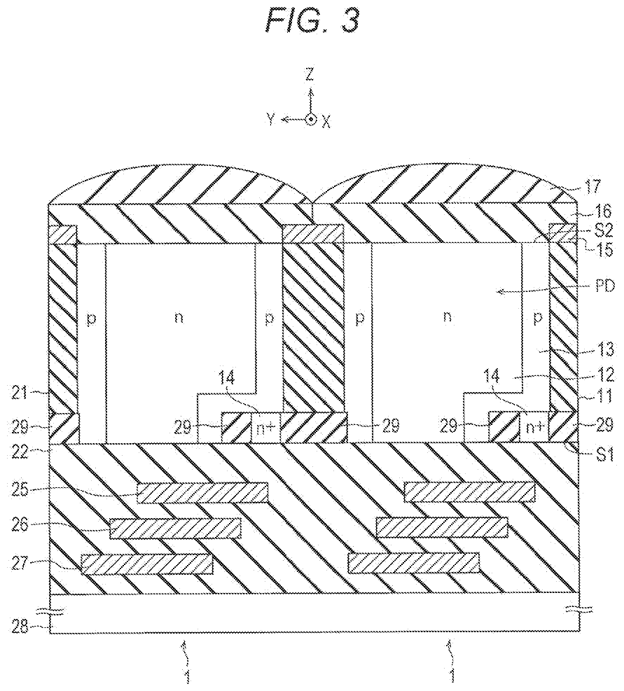

FIG. 3 is another cross-sectional view illustrating a structure of the solid-state imaging device according to the first embodiment. Similarly to FIG. 2, FIG. 3 illustrates a longitudinal cross section of two pixels 1 included in the pixel array region 2. However, FIG. 3 illustrates a YZ cross section unlike FIG. 2 illustrates an XZ cross section.

Each pixel 1 illustrated in FIG. 3 includes structure elements similar to those of each pixel 1 illustrated in FIG. 2. However, a relationship between two pixels 1 illustrated in FIG. 3 is different from the relationship between two pixels 1 illustrated in FIG. 2. Hereinafter, the relationship between these pixels 1 will be described in detail.

Two pixels 1 illustrated in FIG. 3 are adjacent to each other in the Y direction. In the present embodiment, the structures of these pixels 1 are periodically in the Y direction. Specifically, components corresponding to each other in these pixels 1 have a shape periodic in the Y direction and are disposed periodically in the Y direction. The boundary surface between two pixels 1 illustrated in FIG. 3 is located in the element isolation insulation film 21 between these pixels 1 as in FIG. 2. In a case where a pitch between these pixels 1 in the Y direction is P, a pitch between the components corresponding to each other in the Y direction is also P.

Each component in the left pixel 1 illustrated in FIG. 3 is disposed periodically in the Y direction with respect to the corresponding component in the right pixel 1 illustrated in FIG. 3. As an example, the n-type semiconductor region 12, p-type semiconductor region 13, and n⁺-type semiconductor region 14 in the left pixel 1 are respectively disposed periodically in the Y direction with respect to the n-type semiconductor region 12, p-type semiconductor region 13, and n⁺-type semiconductor region 14 in the right pixel 1. Note that each of the n⁺-type semiconductor regions 14 illustrated in FIG. 3 is not a floating diffusion portion for the transfer transistor TG but a source or drain region for a pixel transistor other than the transfer transistor TG or dummy transistor, as will be described later. Therefore, the transfer transistor TG is not illustrated in FIG. 3.

Furthermore, wirings of each of the wiring layers 25 to 27 in the left pixel 1 are disposed periodically in the Y direction with respect to the corresponding wirings of each of the wiring layers 25 to 27 in the right pixel 1. In FIG. 3, one wiring of the wiring layer 25, one wiring of the wiring layer 26, and one wiring of the wiring layer 27 in the left pixel 1 are disposed periodically in the Y direction with respect to one wiring of the wiring layer 25, one wiring of the wiring layer 26, and one wiring of the wiring layer 27 in the right pixel 1, respectively. In the present embodiment, other wirings of each of the wiring layers 25 to 27 in the left pixel 1 are also disposed periodically in the Y direction with respect to the corresponding wirings of each of the wiring layers 25 to 27 in the right pixel 1. Furthermore, the solid-state imaging device of the present embodiment includes a plurality of the element isolation insulation films 29 as illustrated in FIG. 3, and these element isolation insulation films 29 are also disposed periodically in the Y direction. Each of the element isolation insulation films 29 is, for example, a silicon oxide film. The element isolation insulation film 29 is provided under the element isolation insulation film 21 or between the p-type semiconductor region 13 and the n⁺-type semiconductor region 14 in the substrate 11.

Note that, any of the components corresponding to each other in these pixels 1 may not be disposed periodically in the Y direction. For example, any wiring of the wiring layers 25 to 27 in the left pixel 1 may not be disposed periodically in the Y direction with respect to the corresponding wiring of the wiring layers 25 to 27 in the right pixel 1. Furthermore, any wiring of the wiring layers 25 to 27 in the left pixel 1 may not correspond to any wiring of the wiring layers 25 to 27 in the right pixel 1.

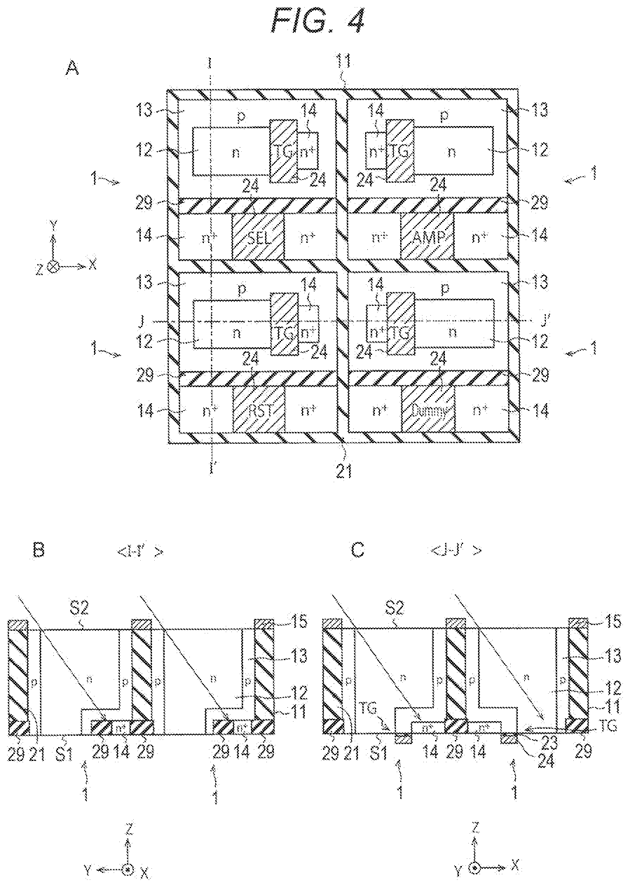

FIG. 4 illustrates a plan view and a cross-sectional view of a structure of the solid-state imaging device according to the first embodiment.

A of FIG. 4 is a plan view illustrating four pixels 1 included in the pixel array region 2, and illustrates a state in which these pixels 1 are viewed in a longitudinal direction. These pixels 1 are adjacent to each other in the Y direction and X direction. The lower left and upper left pixels 1 illustrated in A of FIG. 4 are examples of first and second pixels of the present disclosure. Similarly, the lower right and upper right pixels 1 illustrated in A of FIG. 4 are examples of the first and second pixels of the present disclosure. Moreover, the lower left, upper left, lower right, and upper right pixels 1 illustrated in A of FIG. 4 are examples of the first, second, third, fourth pixels of the present disclosure.

The lower left pixel 1 illustrated in A of FIG. 4 includes a transfer transistor TG and a reset transistor RST on the front surface S1 of the substrate 11. Similarly to the transfer transistor TG illustrated in FIG. 2, the reset transistor RST includes the gate insulation film 23 and the gate electrode 24 which are sequentially provided on the front surface S1 of the substrate 1. The reset transistor RST is an example of a second transistor of the present disclosure.

The upper left pixel 1 illustrated in A of FIG. 4 includes the transfer transistor TG and a selection transistor SEL on the front surface S1 of the substrate 11. Similarly to the transfer transistor TG illustrated in FIG. 2, the selection transistor SEL includes the gate insulation film 23 and the gate electrode 24 which are sequentially provided on the front surface S1 of the substrate 1. The selection transistor SEL is also an example of the second transistor of the present disclosure.

The upper right pixel 1 illustrated in A of FIG. 4 includes the transfer transistor TG and an amplification transistor AMP on the front surface S1 of the substrate 11. Similarly to the transfer transistor TG illustrated in FIG. 2, the amplification transistor AMP includes the gate insulation film 23 and the gate electrode 24 which are sequentially provided on the front surface S1 of the substrate 1. The amplification transistor AMP is also an example of the second transistor of the present disclosure.

The lower right pixel 1 illustrated in A of FIG. 4 includes the transfer transistor TG and a dummy transistor indicated by a reference sign “Dummy” on the front surface S1 of the substrate 11. Similarly to the transfer transistor TG illustrated in FIG. 2, the dummy transistor of the present embodiment includes the gate insulation film 23 and the gate electrode 24 which are sequentially provided on the front surface S1 of the substrate 1. However, the dummy transistor of the present embodiment is not used as a transistor that contributes to the operation of the solid-state imaging device. The dummy transistor is also an example of the second transistor of the present disclosure.

The lower left pixel 1 illustrated in A of FIG. 4 is surrounded by the element isolation insulation film 21 and includes the element isolation insulation film 29 provided in the pixel 1. The element isolation insulation film 29 is provided between the transfer transistor TG and the reset transistor RST in order to isolate the transfer transistor TG from the reset transistor RST. In A of FIG. 4, the element isolation insulation film 29 extends in the X direction, and ends of the element isolation insulation film 29 in the ±X direction are in contact with the element isolation insulation film 21. However, the element isolation insulation film 21 penetrates the substrate 11 from the front surface S1 to the back surface S2, but the element isolation insulation film 29 does not penetrate the substrate 11 from the front surface S1 to the back surface S2. The element isolation insulation film 29 is formed on the front surface S1 side of the substrate 11.

The same applies to the other pixels 1 illustrated in A of FIG. 4. In the upper left pixel 1 illustrated in A of FIG. 4, the element isolation insulation film 29 is provided between the transfer transistor TG and the selection transistor SEL. In the upper right pixel 1 illustrated in A of FIG. 4, the element isolation insulation film 29 is provided between the transfer transistor TG and the amplification transistor AMP. In the lower right pixel 1 illustrated in A of FIG. 4, the element isolation insulation film 29 is provided between the transfer transistor TG and the dummy transistor.

The lower left pixel 1 illustrated in A of FIG. 4 includes one n⁺-type semiconductor region 14 corresponding to the floating diffusion portion for the transfer transistor TG and two n⁺-type semiconductor regions 14 corresponding to the source and drain regions for the reset transistor RST. All of these n⁺-type semiconductor regions 14 are provided under the p-type semiconductor regions 13 in the substrate 11. However, the former of one n⁺-type semiconductor region 14 is provided near the transfer transistor TG, and the latter of two n⁺-type semiconductor regions 14 are provided so as to sandwich the reset transistor RST.

The same applies to the other pixels 1 illustrated in A of FIG. 4. The upper left pixel 1 illustrated in A of FIG. 4 includes one n⁺-type semiconductor region 14 corresponding to the floating diffusion portion for the transfer transistor TG and two n⁺-type semiconductor regions 14 corresponding to the source and drain regions for the selection transistor SEL. The upper right pixel 1 illustrated in A of FIG. 4 includes one n⁺-type semiconductor region 14 corresponding to the floating diffusion portion for the transfer transistor TG and two n⁺-type semiconductor regions 14 corresponding to the source and drain regions for the amplification transistor AMP. The lower right pixel 1 illustrated in A of FIG. 4 includes one n⁺-type semiconductor region 14 corresponding to the floating diffusion portion for the transfer transistor TG and two n⁺-type semiconductor regions 14 corresponding to the source and drain regions for the dummy transistor.

Four pixels 1 illustrated in A of FIG. 4 share the reset transistor RST, the selection transistor SEL, and the amplification transistor AMP. The reset transistor RST is used to initialize the floating diffusion portions (n⁺-type semiconductor regions 14) of these pixels 1, that is, to reset the potential of the floating diffusion portion to the power supply potential (VDD potential). The selection transistor SEL is used to bring these pixels 1 into a selected state. The amplification transistor AMP functions as an input unit of a source follower circuit that reads a voltage signal from the floating diffusion portion of each of these pixels 1.

A relationship among FIG. 2, FIG. 3, and A of FIG. 4 is as follows. FIG. 2 illustrates an XZ cross section of two pixels 1 among four pixels 1 illustrated in A of FIG. 4, and specifically, illustrates a cross section taken along line J-J′ illustrated in A of FIG. 4. FIG. 3 illustrates a YZ cross section of two pixels 1 among four pixels 1 illustrated in A of FIG. 4, and specifically, illustrates a cross section taken along line I-I′ illustrated in A of FIG. 4.

B of FIG. 4 illustrates a longitudinal cross section taken along line I-I′ illustrated in A of FIG. 4, and illustrates a YZ cross section of the solid-state imaging device of the present embodiment, similarly to FIG. 3. However, B of FIG. 4 does not illustrate the color filter 16, the on-chip lens 17, the interlayer insulation film 22, the support substrate 28, and the like.

C of FIG. 4 illustrates a longitudinal cross section taken along line J-J′ illustrated in A of FIG. 4, and illustrates an XZ cross section of the solid-state imaging device of the present embodiment, similarly to FIG. 2. However, C of FIG. 4 does not illustrate the color filter 16, the on-chip lens 17, the interlayer insulation film 22, the support substrate 28, and the like.

Hereinafter, a relationship among four pixels 1 illustrated in A of FIG. 4 will be described. In this description, reference is also made to FIGS. 2, 3, B of FIG. 4, and C of FIG. 4 as appropriate.

In A of FIG. 4, the lower left pixel 1 including the reset transistor RST and the upper left pixel 1 including the selection transistor SEL are adjacent to each other in the Y direction. In the present embodiment, the structures of these pixels 1 are periodically in the Y direction. Specifically, components corresponding to each other in these pixels 1 have a shape periodic in the Y direction and are disposed periodically in the Y direction. For example, the gate electrode 24 of the upper left transfer transistor TG is disposed periodically in the Y direction with respect to the gate electrode 24 of the lower left transfer transistor TG. Moreover, the gate electrode 24 of the selection transistor SEL is disposed periodically in the Y direction with respect to the gate electrode 24 of the reset transistor RST. Moreover, the n-type semiconductor region 12, p-type semiconductor region 13, three n⁺-type semiconductor regions 14, and element isolation insulation film 29 in the upper left pixel 1 are respectively disposed periodically in the Y direction with respect to the n-type semiconductor region 12, p-type semiconductor region 13, three n⁺-type semiconductor regions 14, and element isolation insulation film 29 in the lower left pixel 1.

Furthermore, the lower right pixel 1 including the dummy transistor and the upper right pixel 1 including the amplification transistor AMP are adjacent to each other in the Y direction. In the present embodiment, the structures of these pixels 1 are periodically in the Y direction. Specifically, components corresponding to each other in these pixels 1 have a shape periodic in the Y direction and are disposed periodically in the Y direction. For example, the gate electrode 24 of the upper right transfer transistor TG is disposed periodically in the Y direction with respect to the gate electrode 24 of the lower right transfer transistor TG. Moreover, the gate electrode 24 of the amplification transistor AMP is disposed periodically in the Y direction with respect to the gate electrode 24 of the dummy transistor. Moreover, the n-type semiconductor region 12, p-type semiconductor region 13, three n⁺-type semiconductor regions 14, and element isolation insulation film 29 in the upper right pixel 1 are respectively disposed periodically in the Y direction with respect to the n-type semiconductor region 12, p-type semiconductor region 13, three n⁺-type semiconductor regions 14, and element isolation insulation film 29 in the lower right pixel 1.

Furthermore, the lower left pixel 1 including the reset transistor RST and the lower right pixel 1 including the dummy transistor are adjacent to each other in the X direction. In the present embodiment, the structures of these pixels 1 are symmetrical in the X direction. Specifically, components corresponding to each other in these pixels 1 have a shape symmetrical in the X direction and are disposed symmetrically in the X direction. For example, the gate electrode 24 of the lower right transfer transistor TG is disposed symmetrically in the X direction with respect to the gate electrode 24 of the lower left transfer transistor TG. Moreover, the gate electrode 24 of the dummy transistor is disposed symmetrically in the X direction with respect to the gate electrode 24 of the reset transistor RST. Moreover, the n-type semiconductor region 12, p-type semiconductor region 13, three n⁺-type semiconductor regions 14, and element isolation insulation film 29 in the lower right pixel 1 are respectively disposed symmetrically in the X direction with respect to the n-type semiconductor region 12, p-type semiconductor region 13, three n⁺-type semiconductor regions 14, and element isolation insulation film 29 in the lower left pixel 1.

Furthermore, the upper left pixel 1 including the selection transistor SEL and the upper right pixel 1 including the amplification transistor AMP are adjacent to each other in the X direction. In the present embodiment, the structures of these pixels 1 are symmetrical in the X direction. Specifically, components corresponding to each other in these pixels 1 have a shape symmetrical in the X direction and are disposed symmetrically in the X direction. For example, the gate electrode 24 of the upper right transfer transistor TG is disposed symmetrically in the X direction with respect to the gate electrode 24 of the upper left transfer transistor TG. Moreover, the gate electrode 24 of the amplification transistor AMP is disposed symmetrically in the X direction with respect to the gate electrode 24 of the selection transistor SEL. Moreover, the n-type semiconductor region 12, p-type semiconductor region 13, three n⁺-type semiconductor regions 14, and element isolation insulation film 29 in the upper right pixel 1 are respectively disposed symmetrically in the X direction with respect to the n-type semiconductor region 12, p-type semiconductor region 13, three n⁺-type semiconductor regions 14, and element isolation insulation film 29 in the upper left pixel 1.

In the present embodiment, these relationships are also established in the wiring layers 25 to 27. For example, wirings of each of the wiring layers 25 to 27 in the upper left pixel 1 are disposed periodically in the Y direction with respect to the corresponding wirings of each of the wiring layers 25 to 27 in the lower left pixel 1 (FIG. 3). Similarly, wirings of each of the wiring layers 25 to 27 in the upper right pixel 1 are disposed periodically in the Y direction with respect to the corresponding wirings of each of the wiring layers 25 to 27 in the lower right pixel 1. On the other hand, wirings of each of the wiring layers 25 to 27 in the lower right pixel 1 are disposed symmetrically in the X direction with respect to the corresponding wirings of each of the wiring layers 25 to 27 in the lower left pixel 1 (FIG. 2). Similarly, wirings of each of the wiring layers 25 to 27 in the upper right pixel 1 are disposed symmetrically in the X direction with respect to the corresponding wirings of each of the wiring layers 25 to 27 in the upper left pixel 1.

Note that, any of the components corresponding to each other in these pixels 1 may not be disposed periodically in the Y direction or may not be disposed symmetrically in the X direction. For example, any wiring of the wiring layers 25 to 27 in the upper left pixel 1 may not be disposed periodically in the Y direction with respect to the corresponding wiring of the wiring layers 25 to 27 in the lower left pixel 1. Furthermore, any wiring of the wiring layers 25 to 27 in the lower right pixel 1 may not be disposed symmetrically in the X direction with respect to the corresponding wiring of the wiring layers 25 to 27 in the lower left pixel 1.

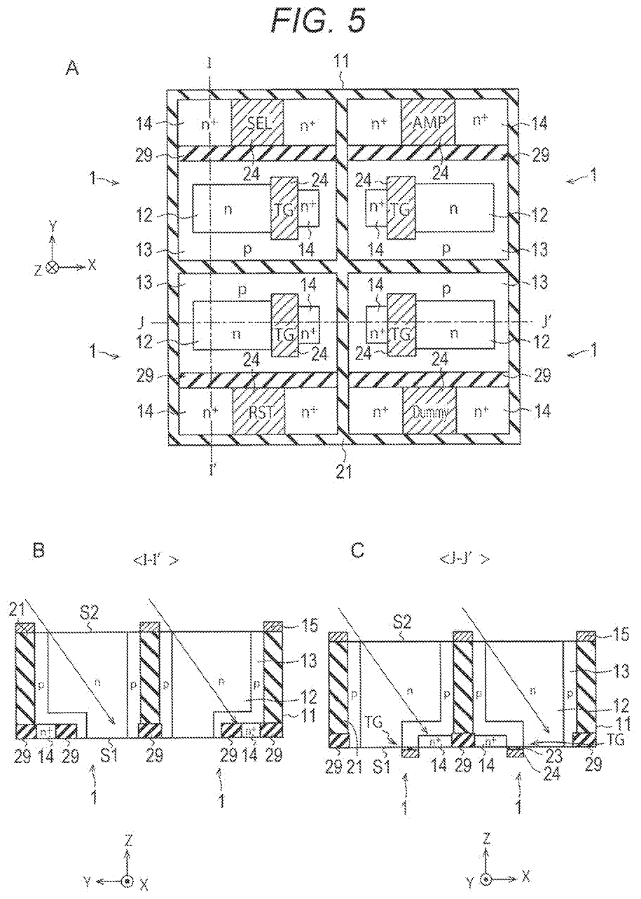

As described above, two pixels 1 adjacent to each other in the X direction have a symmetrical structure in the X direction. As an example of this, C of FIG. 5 illustrates the pixel 1 including the reset transistor RST and the pixel 1 including the dummy transistor. In C of FIG. 5, light incident on these pixels 1 at the same incident angle is indicated by two arrows. In the left pixel 1 illustrated in C of FIG. 5, light is incident on the n⁺-type semiconductor region 14. On the other hand, in the right pixel 1 illustrated in C of FIG. 5, light is not incident on the n⁺-type semiconductor region 14. As described above, when two pixels 1 adjacent to each other have different light incident locations, there is a high possibility that a sensitivity difference is generated between these pixels 1.

On the other hand, two pixels 1 adjacent to each other in the Y direction have a periodic structure in the Y direction. As an example of this, B of FIG. 5 illustrates the pixel 1 including the reset transistor RST and the pixel 1 including the selection transistor SEL. In B of FIG. 5, light incident on these pixels 1 at the same incident angle is indicated by two arrows. In the left pixel 1 illustrated in B of FIG. 5, light is incident on the n⁺-type semiconductor region 14. Similarly, also in the right pixel 1 illustrated in B of FIG. 5, light is incident on the n⁺-type semiconductor region 14. As described above, when two pixels 1 adjacent to each other have the same light incident locations, there is a low possibility that a sensitivity difference is generated between these pixels 1.

According to the present embodiment, since two pixels 1 adjacent to each other in the Y direction have the periodic structure, it is possible to prevent the sensitivity difference from being generated between these pixels 1. On the other hand, when two pixels 1 adjacent to each other in the X direction have the symmetrical structure, there is an advantage that, for example, components in one pixel 1 and components in the other pixel 1 can be electrically connected by a short wiring. According to the present embodiment, it is possible to achieve both suppression of the sensitivity difference and shortening of the wiring.

In the present embodiment, four pixels 1 illustrated in A of FIG. 4 form one unit. The solid-state imaging device of the present embodiment includes a plurality of units arranged in a two-dimensional array in the X direction and the Y direction, and each of the units has the same structure as the unit illustrated in A of FIG. 4. Therefore, in the solid-state imaging device of the present embodiment, a large number of pixels 1 are periodically disposed in the Y direction, and a large number of pixels 1 are disposed symmetrically two by two in the X direction.

FIG. 5 illustrates a plan view and a cross-sectional view of a structure of the solid-state imaging device according to a comparative example of the first embodiment.

A of FIG. 5 is a plan view illustrating four pixels 1 included in the pixel array region 2, and illustrates a state in which these pixels 1 are viewed in a longitudinal direction. B of FIG. 5 illustrates a longitudinal cross section taken along line I-I′ illustrated in A of FIG. 5. C of FIG. 5 illustrates a longitudinal cross section taken along line J-J′ illustrated in A of FIG. 5.

In the present comparative example, two pixels 1 adjacent to each other in the X direction have a symmetrical structure in the X direction. Therefore, as illustrated in C of FIG. 5, there is a high possibility that a sensitivity difference is generated between these pixels 1. Moreover, in the present comparative example, two pixels 1 adjacent to each other in the Y direction have a symmetrical structure in the Y direction. Therefore, as illustrated in B of FIG. 5, there is a high possibility that a sensitivity difference is generated between these pixels 1.

According to the present comparative example, the components in four pixels 1 can be electrically connected by a short wiring. However, according to the present comparative example, there is a high possibility that a sensitivity difference is generated between these pixels 1. On the other hand, according to the present embodiment, it is possible to prevent the sensitivity difference from being generated between the different pixels 1 while the components in the different pixels 1 are electrically connected by a short wiring.

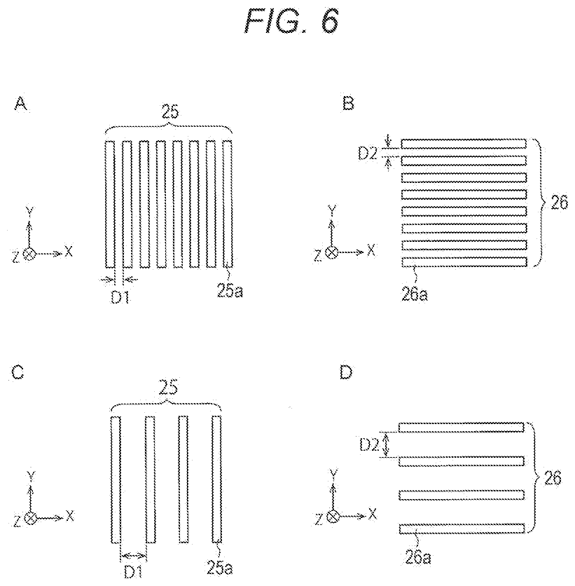

FIG. 6 is a plan view schematically illustrating an example of the wiring layers 25 and 26 according to the first embodiment.

A and B of FIG. 6 illustrate a first example of the wiring layers 25 and 26 of the present embodiment. In this example, the wiring layer 25 includes a plurality of wirings 25a arranged in the X direction and extending in the Y direction, and the wiring layer 26 includes a plurality of wirings 26a arranged in the Y direction and extending in the X direction. Moreover, A and B of FIG. 6 illustrate a distance D1 between the wirings 25a and a distance D2 between the wirings 26a. These wirings 25a are examples of a first wiring of the present disclosure, and these wirings 26a are examples of a second wiring of the present disclosure.

According to the present embodiment, since these wirings 25a and these wirings 26a are disposed so as to intersect each other, most of the light escaping from the front surface S1 of the substrate 11 can be reflected to the substrate 11 by the wirings 25a and 26a. Therefore, the light is prevented from escaping from the substrate 11 to the support substrate 28.

Note that although each of the wirings 25a illustrated in A of FIG. 6 linearly extends in the Y direction, the wiring layer 25 of the present embodiment may include the wirings 25a extending in a curved shape in the Y direction. Similarly, although each of the wirings 25b illustrated in B of FIG. 6 linearly extends in the X direction, the wiring layer 26 of the present embodiment may include the wirings 26a extending in a curved shape in the X direction.

C and D of FIG. 6 illustrate a second example of the wiring layers 25 and 26 of the present embodiment. In this example, as in the first example, the wiring layer 25 includes a plurality of wirings 25a arranged in the X direction and extending in the Y direction, and the wiring layer 26 includes a plurality of wirings 26a arranged in the Y direction and extending in the X direction. However, the distances D1 and D2 in this example are set to be longer than the distances D1 and D2 in the first example.

The distance D1 between the wirings 25a and the distance D2 between the wirings 26a may be short as in the first example, or may be long as in the second example. However, in order to effectively prevent light from escaping from the substrate 11 to the support substrate 28, it is desirable that the distances D1 and D2 are short. For example, in a case where a wavelength of target light is λ, the distances D1 and D2 are desirably set to lengths that do not allow transmission of light having a wavelength of λ.

In the present embodiment, two pixels 1 adjacent to each other in the X direction have a symmetrical structure in the X direction, and two pixels 1 adjacent to each other in the Y direction have a periodic structure in the Y direction. In the present embodiment, this relationship may be applied to a contact plug or a via plug, which is electrically connected to the wiring layers 25 to 27. For example, in two pixels 1 adjacent to each other in the X direction, the contact plugs corresponding to each other may be disposed symmetrically in the X direction. Furthermore, in two pixels 1 adjacent to each other in the Y direction, the via plugs corresponding to each other may be disposed periodically in the Y direction.

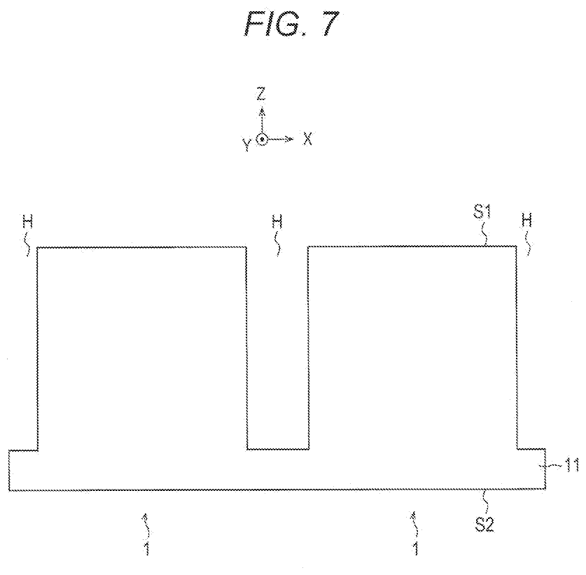

FIGS. 7 to 12 are cross-sectional views illustrating a manufacturing method for the solid-state imaging device according to the first embodiment.

First, an element isolation trench H is formed in the substrate 11 from the front surface S1 of the substrate 11 by photolithography and reactive ion etching (ME) (FIG. 7). The element isolation trench H is used to embed the element isolation insulation film 21 as will described later. However, the element isolation trench H is formed so as not to penetrate the substrate 11. Note that a step of FIG. 7 is performed in a state in which the front surface S1 of the substrate 11 faces upward and the back surface S2 of the substrate 11 faces downward.

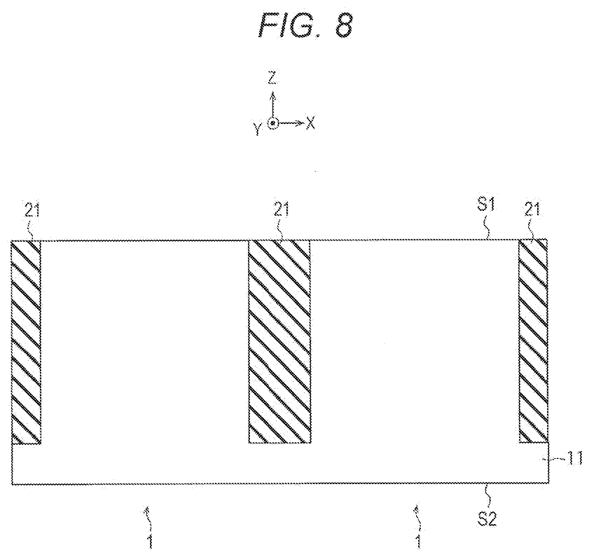

Next, a material of the element isolation insulation film 21 is formed on the front surface S1 of the substrate 11, and an upper surface of the material is planarized by chemical mechanical polishing (CMP) (FIG. 8). As a result, the material outside the element isolation trench H is removed by the CMP, and the element isolation insulation film 21 is formed in the element isolation trench H. Therefore, the region in the substrate 11 is partitioned into a plurality of regions for forming a plurality of the pixels 1 by the element isolation insulation film 21.

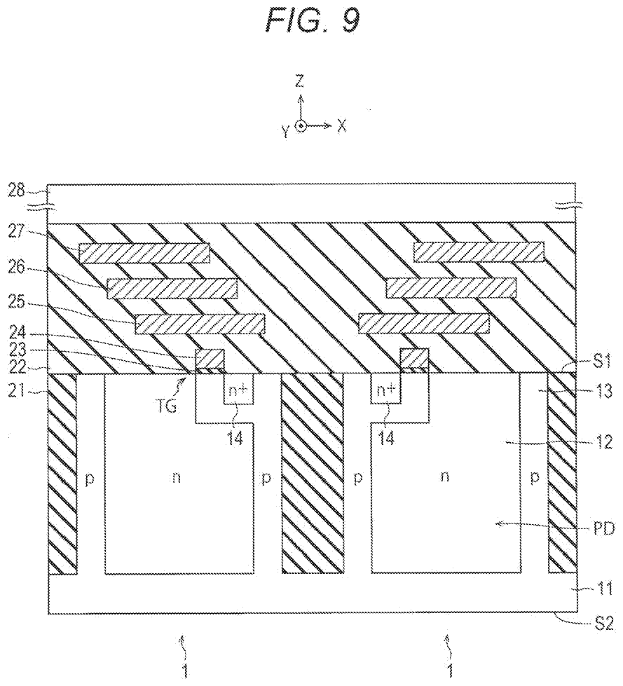

Next, in the substrate 11 or on the substrate 11, the n-type semiconductor region 12, the p-type semiconductor region 13, the n⁺-type semiconductor region 14, the interlayer insulation film 22, the gate insulation film 23, the gate electrode 24, the wiring layer 25, the wiring layer 26, the wiring layer 27, the support substrate 28, and the like are formed (FIG. 9). As a result, the photodiode PD is formed in the substrate 11, and the transfer transistor TG is formed on the substrate 11. The gate insulation film 23 and gate electrode 24 of the reset transistor RST, the selection transistor SEL, the amplification transistor AMP, and the dummy transistor include the same insulation material and the same electrode material as those of the gate insulation film 23 and gate electrode 24 of the transfer transistor TG in a step of FIG. 9. Furthermore, the element isolation insulation film 29 illustrated in A of FIG. 4 is formed in the substrate 11 in any of the steps of FIGS. 7 to 9.

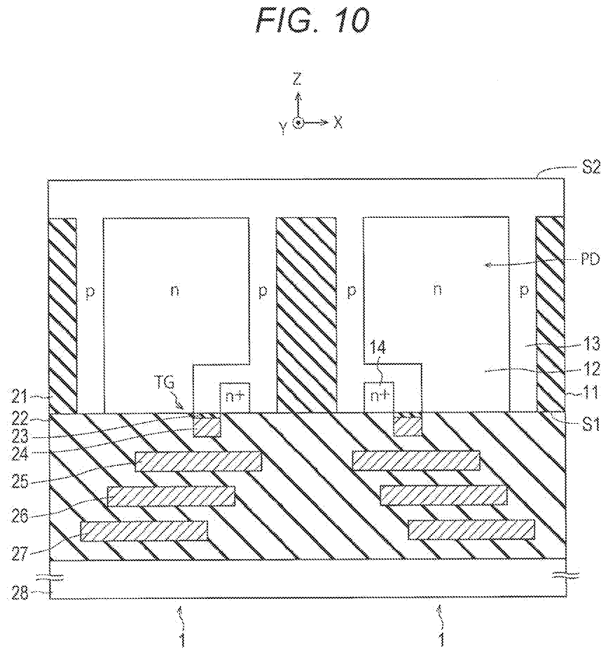

Next, the substrate 11 is turned upside down (FIG. 10). FIG. 10 illustrates a state in which the front surface S1 of the substrate 11 faces downward and the back surface S2 of the substrate 11 faces upward.

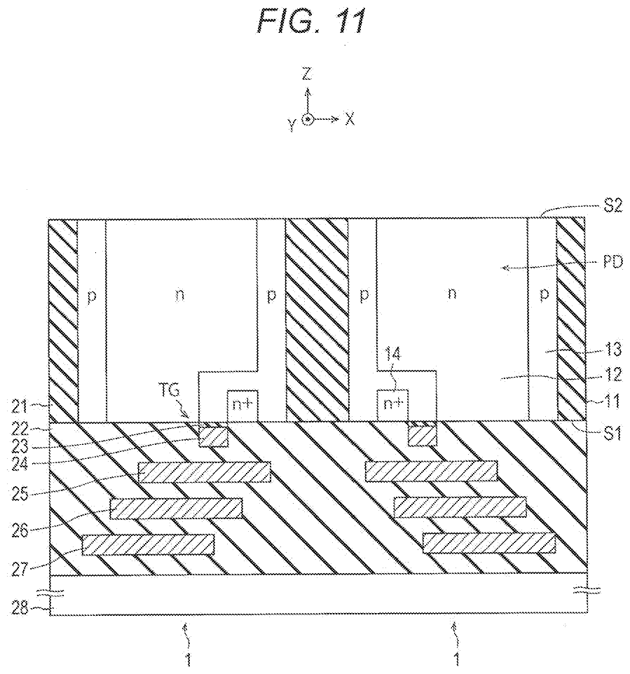

Next, the substrate 11 is thinned from the back surface S2 of the substrate 11 (FIG. 11). As a result, the element isolation insulation film 21 is exposed on the back surface S2 of the substrate 11. In this manner, a structure in which the element isolation insulation film 21 penetrates the substrate 11 is realized. Thinning of the substrate 11 is performed by, for example, etching or CMP.

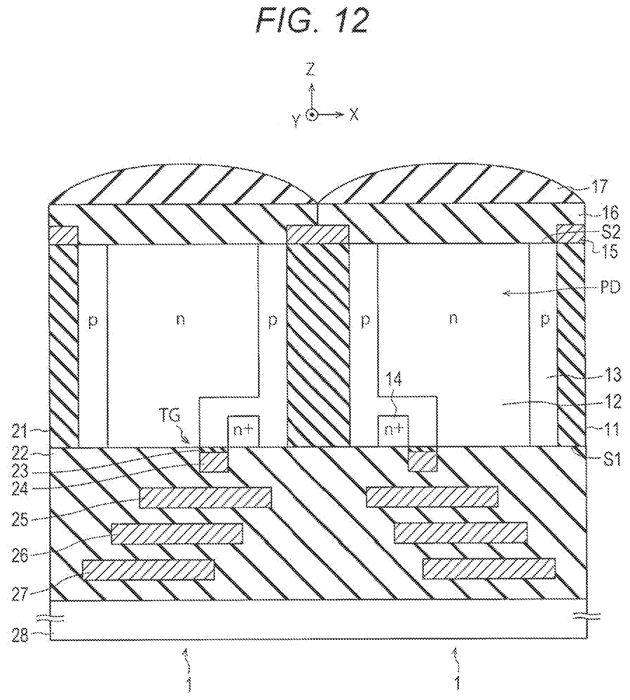

Next, on the back surface S2 of the substrate 11, the light-shielding film 15, the color filter 16, and the on-chip lens 17 are formed (FIG. 12). In this manner, the solid-state imaging device including a plurality of the pixels 1 is manufactured. In the present embodiment, these pixels 1 are formed to have symmetry and periodicity illustrated in A of FIG. 4 and the like.

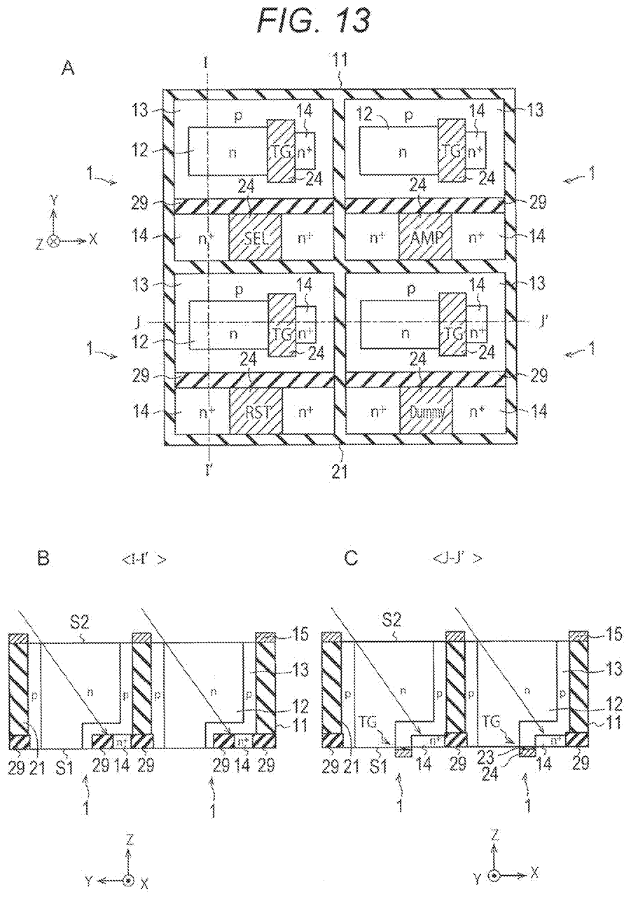

Next, the solid-state imaging device according to a modification example of the present embodiment will be described with reference to FIGS. 13 to 15.

FIG. 13 illustrates a plan view and a cross-sectional view of a structure of the solid-state imaging device according to a modification example of the first embodiment.

A of FIG. 13 is a plan view illustrating four pixels 1 included in the pixel array region 2, and illustrates a state in which these pixels 1 are viewed in a longitudinal direction. B of FIG. 13 illustrates a longitudinal cross section taken along line I-I′ illustrated in A of FIG. 13. C of FIG. 13 illustrates a longitudinal cross section taken along line J-J′ illustrated in A of FIG. 13.

In the present modification example, two pixels 1 adjacent to each other in the Y direction have a periodic structure in the Y direction. Therefore, it is possible to prevent a sensitivity difference from being generated between the pixels 1 adjacent to each other in the Y direction. Moreover, in the present modification example, two pixels 1 adjacent to each other in the X direction have a periodic structure in the X direction. Therefore, it is also possible to prevent the sensitivity difference from being generated between the pixels 1 adjacent to each other in the X direction. Thus, according to the present modification example, it is possible to more effectively prevent the sensitivity difference from being generated between the different pixels 1.

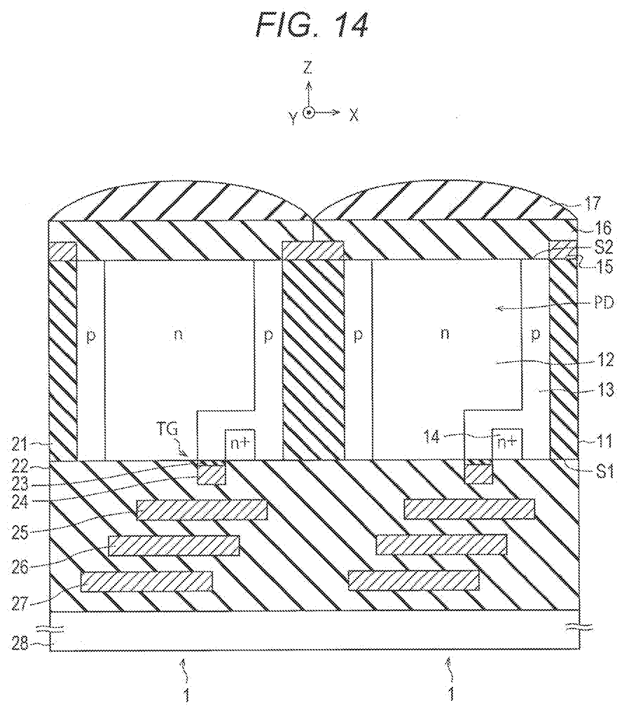

FIG. 14 is a cross-sectional view illustrating a structure of the solid-state imaging device according to a modification example of the first embodiment.

Similarly to C of FIG. 13, FIG. 14 illustrates an XZ cross section of the solid-state imaging device of the present modification example. In FIG. 14, wirings of each of the wiring layers 25 to 27 in the left pixel 1 is disposed periodically in the X direction with respect to the corresponding wirings of each of the wiring layers 25 to 27 in the right pixel 1. Therefore, the sensitivity difference between the pixels 1 can be effectively suppressed.

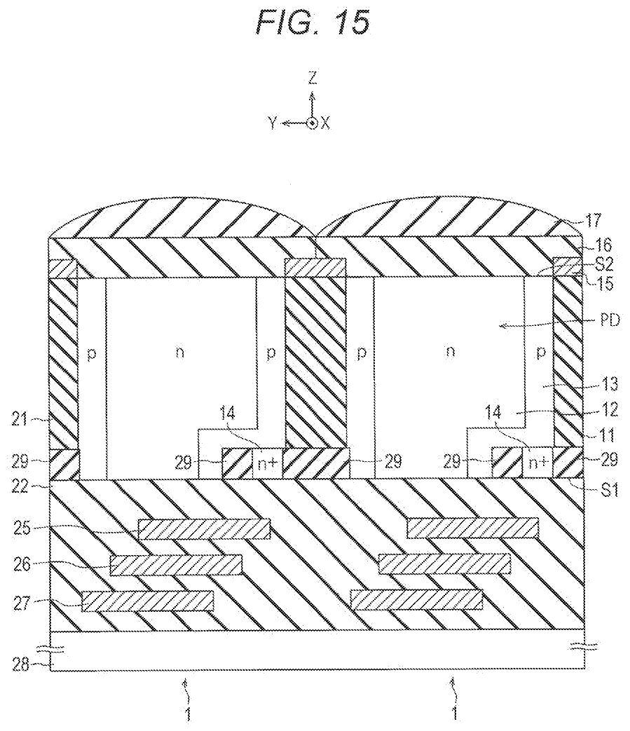

FIG. 15 is another cross-sectional view illustrating a structure of the solid-state imaging device according to the modification example of the first embodiment.

Similarly to B of FIG. 13, FIG. 15 illustrates a YZ cross section of the solid-state imaging device of the present modification example. In FIG. 15, wirings of each of the wiring layers 25 to 27 in the right pixel 1 is disposed periodically in the Y direction with respect to the corresponding wirings of each of the wiring layers 25 to 27 in the left pixel 1. Therefore, the sensitivity difference between the pixels 1 can be effectively suppressed.

As described above, in the present embodiment, two pixels 1 adjacent to each other in the Y direction have a periodic structure in the Y direction. For example, the transfer transistor TG of one pixel 1 is disposed periodically in the Y direction with respect to the transfer transistor TG of the other pixel 1. Furthermore, the n-type semiconductor region 12, p-type semiconductor region 13, and n⁺-type semiconductor region 14 in one pixel 1 are respectively disposed periodically in the Y direction with respect to the n-type semiconductor region 12, p-type semiconductor region 13, and n⁺-type semiconductor region 14 in the other pixel 1. Thus, according to the present embodiment, it is possible to prevent the sensitivity difference from being generated between these pixels 1.

Note that in the present embodiment, two pixels 1 adjacent to each other in the Y direction may have a symmetrical structure in the Y direction, and two pixels 1 adjacent to each other in the X direction may have a periodic structure in the X direction.

### Second Embodiment

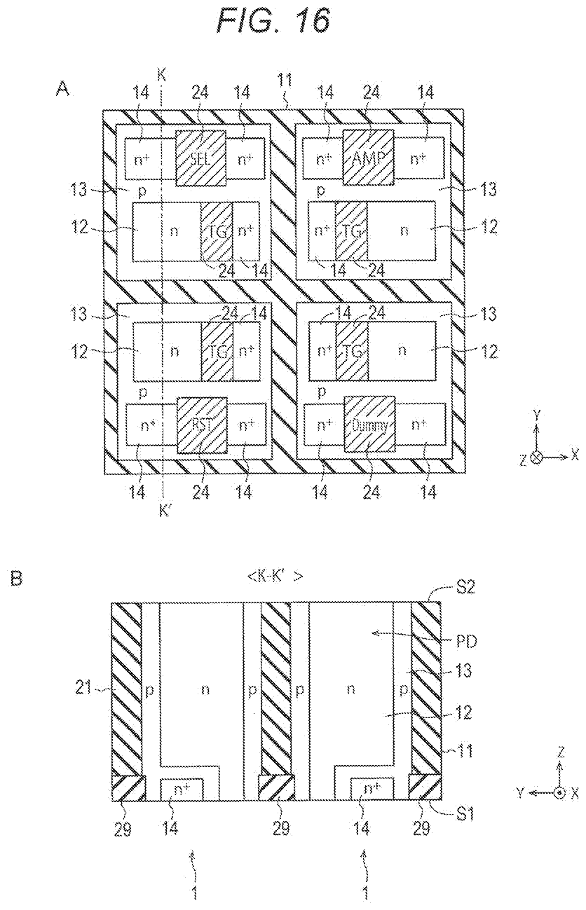

FIG. 16 illustrates a plan view and a cross-sectional view of a structure of a solid-state imaging device according to the second embodiment. The solid-state imaging device of the present embodiment will be described focusing on a difference from the solid-state imaging device of the first embodiment, and the description of common points with the solid-state imaging device of the first embodiment will be omitted.

A of FIG. 16 is a plan view illustrating four pixels 1 included in the pixel array region 2, and illustrates a state in which these pixels 1 are viewed in a longitudinal direction. B of FIG. 16 illustrates a YZ cross section taken along line K-K′ illustrated in A of FIG. 16.

The solid-state imaging device of the present embodiment generally has the structure similar to that of the solid-state imaging device of the comparative example of the first embodiment illustrated in A to C of FIG. 5. Thus, in the present embodiment, two pixels 1 adjacent to each other in the X direction have a symmetrical structure in the X direction, and two pixels 1 adjacent to each other in the Y direction have the symmetrical structure in the Y direction.

However, the lower left pixel 1 illustrated in A of FIG. 16 does not include the element isolation insulation film 29 between the transfer transistor TG and the reset transistor RST. In the present embodiment, the p-type semiconductor region 13 is provided between the transfer transistor TG and the reset transistor RST instead of the element isolation insulation film 29. The p-type impurity concentration of the p-type semiconductor region 13 between the transfer transistor TG and the reset transistor RST may be the same as or different from the p-type impurity concentration of other portions in the p-type semiconductor region 13.

The same applies to the other pixels 1 illustrated in A of FIG. 16. The upper left pixel 1 illustrated in A of FIG. 16 does not include the element isolation insulation film 29 between the transfer transistor TG and the selection transistor SEL. The upper right pixel 1 illustrated in A of FIG. 16 does not include the element isolation insulation film 29 between the transfer transistor TG and the amplification transistor AMP. The lower right pixel 1 illustrated in A of FIG. 16 does not include the element isolation insulation film 29 between the transfer transistor TG and the dummy transistor.

As illustrated in B of FIG. 16, the element isolation insulation film 29 of the present embodiment is provided under the element isolation insulation film 21 in the substrate 11, and has a planar shape generally similar to that of the element isolation insulation film 21. In the present embodiment, the element isolation insulation film penetrating the substrate 11 is formed by the element isolation insulation film 21 and the element isolation insulation film 29. The element isolation insulation films 21 and 29 can be formed, for example, by sequentially forming the element isolation insulation films 21 and 29 in the steps of FIGS. 7 and 8.

In a case where the element isolation insulation film 29 is provided between the transfer transistor TG and the reset transistor RST, there is a possibility that light incident into the substrate 11 is reflected by the element isolation insulation film 29. Such reflected light may cause color mixing between the pixels 1.

The solid-state imaging device according to the present embodiment does not include the element isolation insulation film 29 between the transfer transistor TG and the reset transistor RST. Therefore, according to the present embodiment, it is possible to suppress the color mixing between the pixels 1 due to the element isolation insulation film 29.

The solid-state imaging device of the present embodiment can be realized by, for example, omitting the step of forming the element isolation insulation film 29 between the transfer transistor TG and the reset transistor RST when the solid-state imaging device is manufactured by the method illustrated in FIGS. 7 to 12. In order to make the p-type impurity concentration of the p-type semiconductor region 13 between the transfer transistor TG and the reset transistor RST different from the p-type impurity concentration of other portions in the p-type semiconductor region 13, necessary processing is performed in a step of FIG. 9.

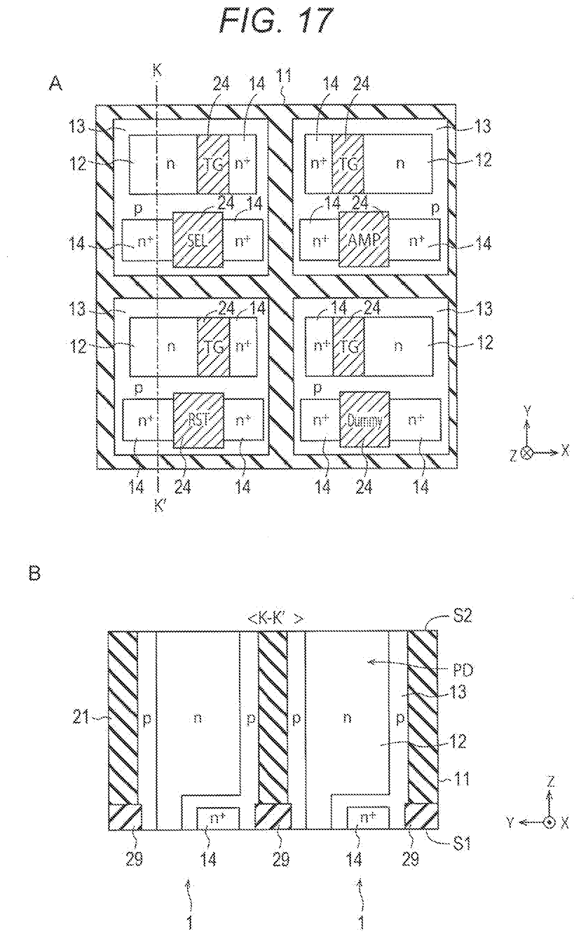

FIG. 17 illustrates a plan view and a cross-sectional view of a structure of the solid-state imaging device according to a modification example of the second embodiment.

A of FIG. 17 is a plan view illustrating four pixels 1 included in the pixel array region 2, and illustrates a state in which these pixels 1 are viewed in a longitudinal direction. B of FIG. 17 illustrates a YZ cross section taken along line K-K′ illustrated in A of FIG. 17.

In the present modification example, two pixels 1 adjacent to each other in the Y direction have a periodic structure in the Y direction similarly to that of the solid-state imaging device illustrated in A of FIG. 4 and the like. Therefore, it is possible to prevent a sensitivity difference from being generated between the pixels 1 adjacent to each other in the Y direction. Moreover, according to the present modification example, it is possible to prevent the sensitivity difference from being generated between the different pixels 1 while the components in the different pixels 1 are electrically connected by a short wiring.

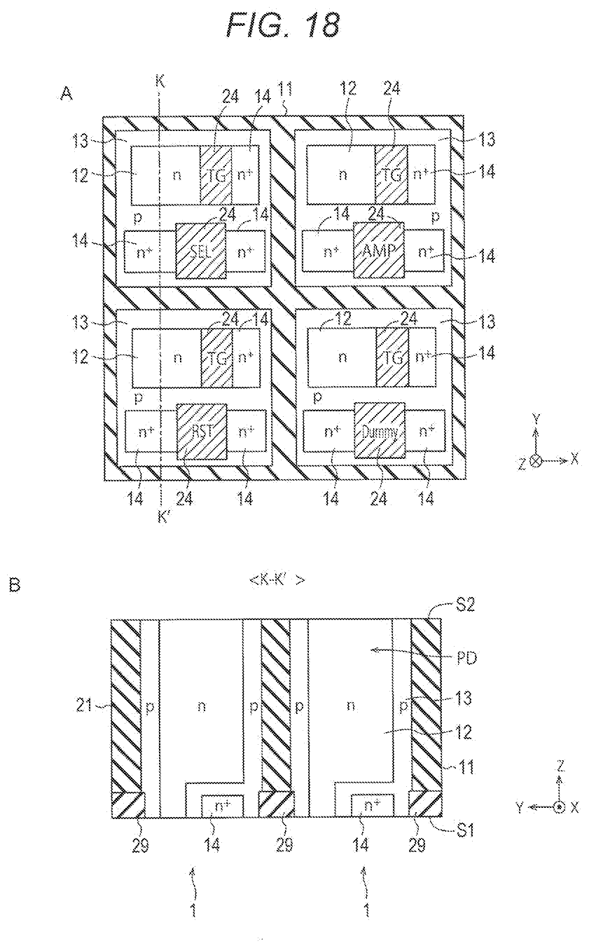

FIG. 18 illustrates a plan view and a cross-sectional view of a structure of the solid-state imaging device according to another modification example of the second embodiment.

A of FIG. 18 is a plan view illustrating four pixels 1 included in the pixel array region 2, and illustrates a state in which these pixels 1 are viewed in a longitudinal direction. B of FIG. 18 illustrates a YZ cross section taken along line K-K′ illustrated in A of FIG. 18.

In the present modification example, similarly to that of the solid-state imaging device illustrated in A of FIG. 13 and the like, two pixels 1 adjacent to each other in the Y direction have a periodic structure in the Y direction, and two pixels 1 adjacent to each other in the X direction have a periodic structure in the X direction. Therefore, it is possible to more effectively prevent the sensitivity difference from being generated between the different pixels 1.

As described above, the solid-state imaging device according to the present embodiment does not include the element isolation insulation film 29 between the transfer transistor TG and the reset transistor RST. Therefore, according to the present embodiment, it is possible to suppress the color mixing between the pixels 1 due to the element isolation insulation film 29.

### Third Embodiment

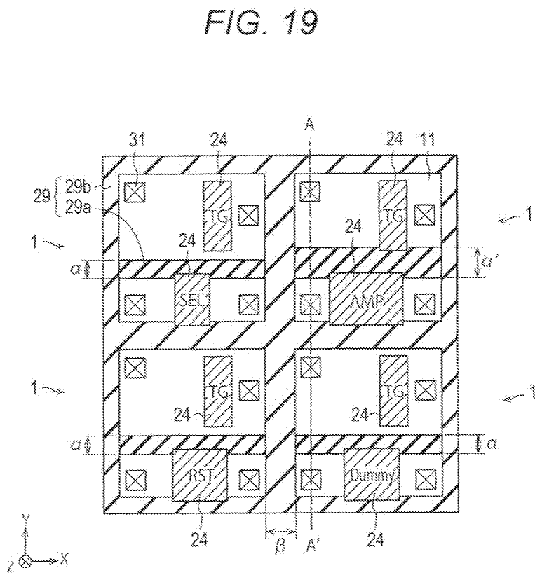

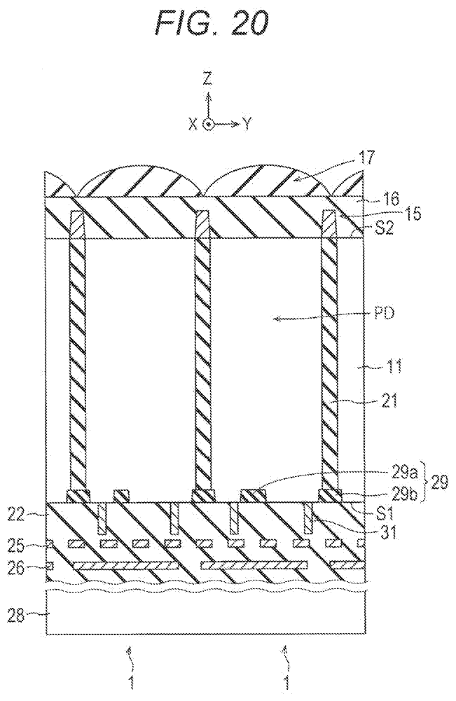

FIG. 19 and FIG. 20 respectively illustrate a plan view and a cross-sectional view of a structure of the solid-state imaging device according to the third embodiment. The solid-state imaging device of the present embodiment will be described focusing on a difference between the solid-state imaging devices of the first and second embodiments, and the description of common points between the solid-state imaging devices of the first and second embodiments will be omitted.

FIG. 19 is a plan view illustrating four pixels 1 included in the pixel array region 2, and illustrates a state in which these pixels 1 are viewed in a longitudinal direction. FIG. 20 illustrates a YZ cross section taken along line A-A′ illustrated in FIG. 19. Hereinafter, the structure of the solid-state imaging device of the present embodiment will be described with reference to FIG. 19, and FIG. 20 will also be appropriately referred to in the description.

The solid-state imaging device of the present embodiment generally has the structure similar to that of the solid-state imaging device of the modification example of the first embodiment illustrated in FIGS. 13 to 15. Thus, in the present embodiment, two pixels 1 adjacent to each other in the X direction generally have a periodic structure in the X direction, and two pixels 1 adjacent to each other in the Y direction generally have the periodic structure in the Y direction. As a result, four pixels 1 illustrated in FIG. 19 have a generally periodic structure in the X direction and the Y direction. For example, each of the gate electrodes 24 of four transfer transistors TG illustrated in FIG. 19 is disposed near the upper right corner (corner in the +X direction and the +Y direction) in the corresponding pixel 1. Furthermore, each pixel 1 illustrated in FIG. 19 includes four contact plugs 31 under the substrate 11 (see also FIG. 20), and these contact plugs 31 of four pixels 1 illustrated in FIG. 19 are also periodically disposed in the X direction and the Y direction.

However, in four pixels 1 illustrated in FIG. 19, the areas of the gate electrodes 24 of the reset transistor RST, selection transistor SEL, amplification transistor AMP, and dummy transistor (Dummy) in plan view are not set to be the same. Specifically, the area of the gate electrode 24 of the amplification transistor AMP is set to be larger than the area of the gate electrode 24 of the reset transistor RST and the area of the gate electrode 24 of the dummy transistor. Furthermore, the area of the gate electrode 24 of the selection transistor SEL is set to be smaller than the area of the gate electrode 24 of the reset transistor RST and the area of the gate electrode 24 of the dummy transistor. On the other hand, the area of the gate electrode 24 of the reset transistor RST and the area of the gate electrode 24 of the dummy transistor are set to be the same. As described above, these transistors illustrated in FIG. 19 include the gate electrodes 24 having two or more types (here, three types) of areas in plan view.

Furthermore, the solid-state imaging device of the present embodiment includes an element isolation insulation film 21 reaching the back surface S2 of the substrate 11 and an element isolation insulation film 29 not reaching the back surface S2 of the substrate 11 (see also FIG. 20), and the element isolation insulation film 29 of the present embodiment includes a plurality of internal element isolation insulation films 29a and an external element isolation insulation film 29b. The element isolation insulation film 21, each of the internal element isolation insulation films 29a, and the external element isolation insulation film 29b are silicon oxide films in the present embodiment, but may be other insulation films (for example, silicon nitride films). The internal element isolation insulation film 29a and the external element isolation insulation film 29b are examples of first and second element isolation insulation films of the present disclosure, respectively.

Each internal element isolation insulation film 29a is provided inside each pixel 1 and is interposed between the transfer transistor TG of each pixel 1 and another pixel transistor (reset transistor RST, the selection transistor SEL, the amplification transistor AMP, or the dummy transistor). FIG. 19 illustrates four internal element isolation insulation films 29a provided in four pixels 1. These internal element isolation insulation films 29a are provided in the substrate 11 on the front surface S1 side of the substrate 11 (see also FIG. 20) and extend in the X direction. Reference signs α and α′ indicate the widths of the internal element isolation insulation films 29a in plan view. Almost all the internal element isolation insulation films 29a illustrated in FIG. 19 have a width α, but have a width α′ in the pixel 1 (upper right pixel 1) including the amplification transistor AMP. The width α′ is set to be thicker than the width α. The width α is an example of a first width of the present disclosure, and the width α′ is an example of a second width of the present disclosure.

The external element isolation insulation film 29b is provided outside each pixel 1, and extends in the X direction and the Y direction between the pixels 1 adjacent to each other. The external element isolation insulation film 29b has a planar shape similar to that of the element isolation insulation film 21, and has a shape surrounding each of four pixels 1 illustrated in FIG. 19. The external element isolation insulation film 29b is provided in the substrate 11 on the front surface S1 side of the substrate 11 (see also FIG. 20), and the element isolation insulation film 21 is provided on the external element isolation insulation film 29b in the substrate 11. As a result, the element isolation insulation film 21 of the present embodiment penetrates the substrate 11 together with the external element isolation insulation film 29b. Reference sign β indicates the width of the external element isolation insulation film 29b in plan view. The external element isolation insulation film 29b of the present embodiment has a width β in any portion.

Note that FIG. 19 illustrates a portion sandwiched between four pixels 1 and a portion surrounding the entire four pixels 1 as a portion of the external element isolation insulation film 29b. Note that FIG. 19 illustrates only half of the latter portion. Therefore, the width of the latter portion is not β/2, but β similarly to the width of the former portion.

FIG. 19 illustrates planar shapes of the internal element isolation insulation film 29a and the external element isolation insulation film 29b of the present embodiment. The internal element isolation insulation film 29a of the present embodiment has generally the same planar shape as that of the element isolation insulation film 29 of the modification example of the first embodiment illustrated in FIG. 13, but includes not only a portion having the width α but also a portion having the width α′. Furthermore, the external element isolation insulation film 29b of the present embodiment has generally the same planar shape as that of the element isolation insulation film 21 of the modification example of the first embodiment illustrated in FIG. 13. Note that the element isolation insulation film 21 according to the modification example of the first embodiment is also provided on the element isolation insulation film 29 (see FIG. 15), but the illustration of the element isolation insulation film 29 under the element isolation insulation film 21 is omitted in the plan view of FIG. 13. The same applies to other plan views of the first and second embodiments.

The solid-state imaging device of the present embodiment can be realized, for example, by forming the internal element isolation insulation films 29a and the external element isolation insulation film 29b as the element isolation insulation film 29 when the solid-state imaging device is manufactured by the method illustrated in FIGS. 7 to 12. The element isolation trench for the element isolation insulation film 29 can be formed in the substrate 11 by lithography and etching. Furthermore, the portion having the width α and the portion having the width α′ can be formed by providing a pattern corresponding to the former and a pattern corresponding to the latter on a photomask for lithography.

Hereinafter, details of the solid-state imaging device according to the third embodiment will be further described subsequently with reference to FIG. 19.

The solid-state imaging device of the present embodiment is, for example, a near-infrared light (NIR) sensor. In this case, each pixel 1 of the present embodiment is used as an NIR pixel for detecting near-infrared light, and a color filter 16 (FIG. 20) for these pixels 1 is a near-infrared light filter.

Four pixels 1 illustrated in FIG. 19 share the pixel transistors (reset transistor RST, the selection transistor SEL, the amplification transistor AMP, and the dummy transistor) other than the transfer transistor TG. In the present embodiment, these four pixels 1 are all NIR pixels.

The sharing of the pixel transistor between the pixels 1 is performed, for example, to reduce the chip size of the solid-state imaging device. However, when such sharing is performed, the symmetry and periodicity of pixel transistors and wirings may deteriorate between these pixels 1 (sharing pixels). For example, in the present embodiment, the size of the amplification transistor AMP is different from the size of the reset transistor RST and the size of the dummy transistor. This is to increase the size of the amplification transistor AMP to reduce noise of the amplification transistor AMP.

The influence of the deterioration in symmetry and periodicity is also applied to imaging characteristics of the NIR sensor. The near-infrared light is less likely to be absorbed by a silicon substrate (substrate 11) as compared with visible light, and easily reaches each pixel transistor without much decrease in intensity. Therefore, in a case where the near-infrared light is detected, the influence of symmetry and periodicity is more strongly applied to the imaging characteristics than a case where the visible light is detected. In the NIR sensor, for example, a large sensitivity difference is likely to be generated between the sharing pixels.

As a technique of correcting the sensitivity difference between the sharing pixels, for example, there is a technique of correcting an opening of the light-shielding film 15 (FIG. 20). The opening size of the light-shielding film 15 is reduced in the pixel 1 having high sensitivity, and thus the output of the pixel 1 having high sensitivity can be matched with the output of the pixel 1 having low sensitivity. However, there is a possibility that quantum efficiency (Qe) of the NIR sensor is decreased. Furthermore, it may be difficult to adjust the opening size of the light-shielding film 15 in design depending on the type of NIR sensor.

In the present embodiment, in order to correct the sensitivity difference between the sharing pixels, the width of the internal element isolation insulation film 29a is adjusted for each pixel 1. Therefore, it is possible to correct the sensitivity difference between the sharing pixels without decreasing the Qe of the NIR sensor. The element isolation insulation films 21 and 29 of the present embodiment are silicon oxide films and have a property of reflecting light. The light reflected by the element isolation insulation films 21 and 29 can contribute to the sensitivity of the pixel 1. Thus, according to the present embodiment, by adjusting the width of the internal element isolation insulation film 29a for each pixel 1, the influence of the internal element isolation insulation film 29a on the sensitivity can be adjusted for each pixel 1, and thus the sensitivity difference between the sharing pixels can be reduced.

In the present embodiment, when the internal element isolation insulation film 29a of a certain pixel 1 is thickened, the light component reflected by the internal element isolation insulation film 29a increases, and the sensitivity of the pixel 1 increases. Thus, in a case where the sensitivity difference between the sharing pixels is corrected using this technology, the internal element isolation insulation film 29a of the pixel 1 having low sensitivity is generally thickened. Therefore, the output of the pixel 1 having low sensitivity can be matched with the output of the pixel 1 having high sensitivity, and the decrease in Qe of the NIR sensor can be suppressed.

Note that the structure of the internal element isolation insulation film 29a of the present embodiment may be applied to a solid-state imaging device other than the NIR sensor. Furthermore, in the present embodiment, the width of the internal element isolation insulation film 29a of the pixel 1 other than the pixel 1 including the amplification transistor AMP may be adjusted. Furthermore, in the present embodiment, the sensitivity difference between the sharing pixels may be corrected by adjusting the width of the external element isolation insulation film 29b instead of the width of the internal element isolation insulation film 29a.

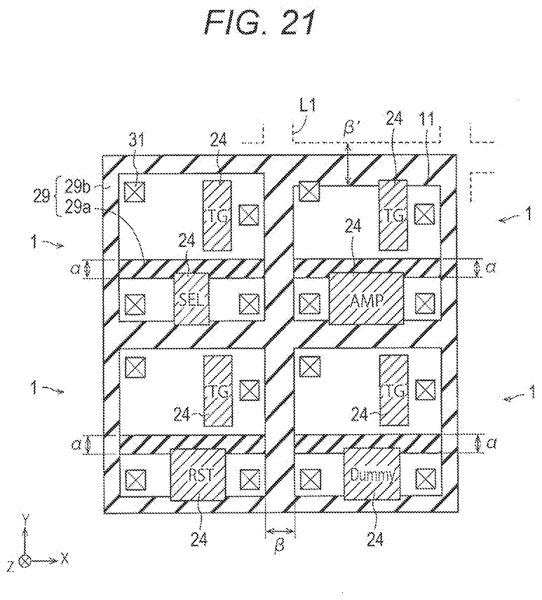

FIG. 21 is a plan view illustrating a structure of the solid-state imaging device according to a first modification example of the third embodiment.

Similarly to FIG. 19, FIG. 21 illustrates four pixels 1 included in the pixel array region 2 and the element isolation insulation film 29 for these pixels 1. Moreover, in FIG. 21, in order to describe the shape of the element isolation insulation film 29, the shape of the element isolation insulation film 29 around these pixels 1 is indicated by a dotted line L1.

The internal element isolation insulation film 29a of the present modification example has the width α in any portion. On the other hand, the external element isolation insulation film 29b of the present modification example has the width β almost entirely, but has a width β′ in the +Y direction of the pixel 1 including the amplification transistor AMP. The width β′ is set to be thicker than the width β. The width β is an example of a first width of the present disclosure, and the width β′ is an example of a second width of the present disclosure. According to the present modification example, the sensitivity difference between the sharing pixels can be corrected by adjusting the width of the external element isolation insulation film 29b.

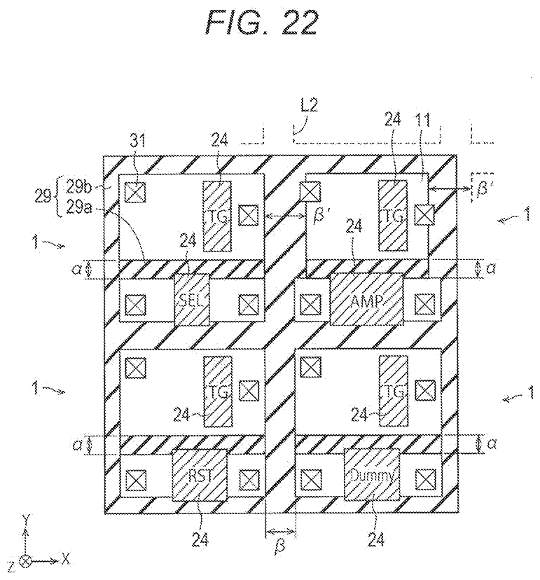

FIG. 22 is a plan view illustrating a structure of the solid-state imaging device according to a second modification example of the third embodiment.

Similarly to FIG. 19, FIG. 22 illustrates four pixels 1 included in the pixel array region 2 and the element isolation insulation film 29 for these pixels 1. Moreover, in FIG. 22, in order to describe the shape of the element isolation insulation film 29, the shape of the element isolation insulation film 29 around these pixels 1 is indicated by a dotted line L2.

The internal element isolation insulation film 29a of the present modification example has the width α in any portion. On the other hand, the external element isolation insulation film 29b of the present modification example has the width β almost entirely, but has a width β′ in the ±X direction of the pixel 1 including the amplification transistor AMP. According to the present modification example, the sensitivity difference between the sharing pixels can be corrected by adjusting the width of the external element isolation insulation film 29b at a plurality of portions.

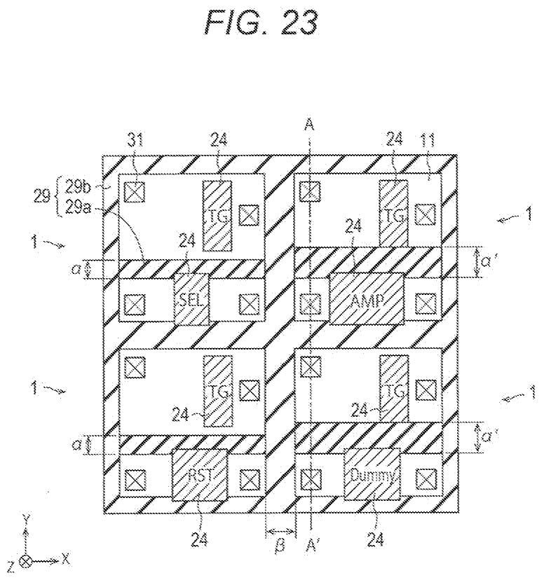

FIG. 23 is a plan view illustrating a structure of the solid-state imaging device according to a third modification example of the third embodiment.

The external element isolation insulation film 29b of the present modification example has a width β in any portion. On the other hand, the internal element isolation insulation film 29a of the present modification example has the width α in the pixel 1 including the reset transistor RST or the selection transistor SEL, but has the width α′ in the pixel 1 including the amplification transistor AMP or the dummy transistor. According to the present modification example, the sensitivity difference between the sharing pixels can be corrected by adjusting the widths of the internal element isolation insulation films 29a in a plurality of the pixels 1.

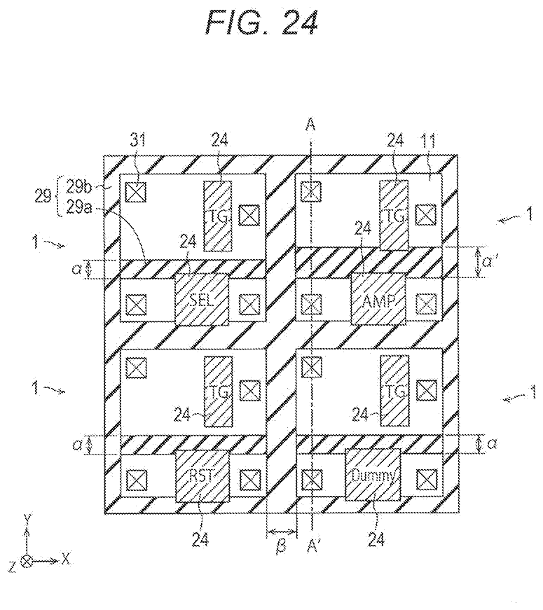

FIG. 24 is a plan view illustrating a structure of the solid-state imaging device according to a fourth modification example of the third embodiment.

In the present modification example, the areas of the gate electrodes 24 of the reset transistor RST, selection transistor SEL, amplification transistor AMP, and dummy transistor in plan view are set to be the same. Moreover, the reset transistor RST, selection transistor SEL, amplification transistor AMP, and dummy transistor of the present modification example are disposed periodically in the X direction and the Y direction similarly to the transfer transistor TG. Specifically, each of the gate electrodes 24 of the reset transistor RST, selection transistor SEL, amplification transistor AMP, and dummy transistor of the present modification example is disposed in the −Y direction of the internal element isolation insulation film 29a near the center of the internal element isolation insulation film 29a in the corresponding pixel 1.

On the other hand, the element isolation insulation film 29 of the present modification example has the same shape as that of the element isolation insulation film 29 illustrated in FIG. 19. Thus, the external element isolation insulation film 29b of the present modification example has a width β in any portion. Furthermore, almost all the internal element isolation insulation films 29a of the present modification example have a width α, but have a width α′ in the pixel 1 including the amplification transistor AMP. According to the present modification example, the sensitivity difference between the sharing pixels can be corrected by adjusting the width of the internal element isolation insulation film 29a.

In the present modification example, the areas of the gate electrodes 24 of the reset transistor RST, selection transistor SEL, amplification transistor AMP, and dummy transistor in plan view are set to be the same. Therefore, the sensitivity difference between the sharing pixels, which is caused by these pixel transistors, is not generally generated. However, in a case where the shapes of the wirings (for example, the wirings in the wiring layers 25 to 27) of the solid-state imaging device of the present modification example are different between the shared pixels, the sensitivity difference between the sharing pixels may be generated. According to the present modification example, the sensitivity difference can be reduced. Note that in the present modification example, instead of adopting the shape of the element isolation insulation film 29 illustrated in FIG. 19, the shape of the element isolation insulation films 29 of the first, second, or third modification examples may be adopted.

As described above, the element isolation insulation film 29a (or 29b) of the present embodiment includes a portion having the width α (or β) and a portion having the width α′ (or β′). Therefore, according to the present embodiment, the sensitivity difference can be prevented from being generated between the pixels 1 by adjusting the width of the element isolation insulation film 29a (or 29b).

Note that the internal element isolation insulation film 29a or external element isolation insulation film 29b of the present embodiment may have three or more types of widths. Furthermore, in the solid-state imaging device of the present embodiment, the internal element isolation insulation film 29a may have two or more types of widths, and the external element isolation insulation film 29b may have two or more types of widths.

Hereinafter, the solid-state imaging devices according to fourth to ninth embodiments will be described. The solid-state imaging devices of the fourth to ninth embodiments will be described focusing on a difference from the solid-state imaging devices of the first to third embodiments, and the description of common points with the solid-state imaging devices of the first to third embodiments will be omitted.

### Fourth Embodiment

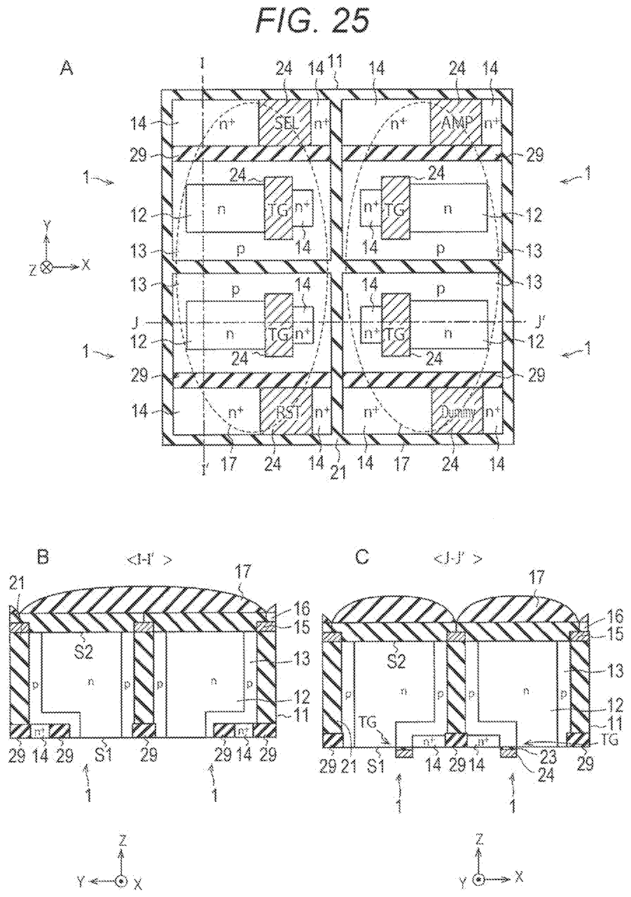

FIG. 25 illustrates a plan view and a cross-sectional view of a structure of the solid-state imaging device according to the fourth embodiment.

A of FIG. 25 is a plan view illustrating four pixels 1 included in the pixel array region 2, and illustrates a state in which these pixels 1 are viewed in a longitudinal direction. B of FIG. 25 illustrates a longitudinal cross section taken along line I-I′ illustrated in A of FIG. 25. C of FIG. 25 illustrates a longitudinal cross section taken along line J-J′ illustrated in A of FIG. 25.

The solid-state imaging device of the present embodiment generally has the structure similar to that of the solid-state imaging device of the comparative example of the first embodiment illustrated in A to C of FIG. 5. Thus, in the present embodiment, the corresponding components in two pixels 1 adjacent to each other in the X direction generally have a symmetrical structure in the X direction, and the corresponding components in two pixels 1 adjacent to each other in the Y direction generally have the symmetrical structure in the Y direction.

However, as illustrated in A of FIG. 25, the gate electrodes 24 of the reset transistor RST, selection transistor SEL, amplification transistor AMP, and dummy transistor indicated by the reference sign “Dummy” are disposed periodically in the X direction and disposed symmetrically in the Y direction. For example, the gate electrode 24 of the selection transistor SEL is disposed symmetrically in the Y direction with respect to the gate electrode 24 of the reset transistor RST. Furthermore, the gate electrode 24 of the selection transistor SEL is disposed periodically in the X direction with respect to the gate electrode 24 of the amplification transistor AMP.

A to C of FIG. 25 illustrate two on-chip lenses 17 in these pixels 1. One on-chip lens 17 is provided in common on the upper left and lower left pixels 1 illustrated in A of FIG. 25. Thus, the light condensed by this on-chip lens 17 is incident on the photodiode PD in these two pixels 1. In the similar manner, the other on-chip lens 17 is provided in common on the upper right and lower right pixels 1 illustrated in A of FIG. 25. Thus, the light condensed by this on-chip lens 17 is incident on the photodiode PD in these two pixels 1.

In A of FIG. 25, the gate electrode 24 of the reset transistor RST and the gate electrode 24 of the selection transistor SEL are disposed near a lower right corner and upper right corner of the corresponding on-chip lens 17, respectively. Therefore, these gate electrodes 24 are disposed at positions separated from the optical axis of this on-chip lens 17. Therefore, it is possible to prevent these gate electrodes 24 from hindering the incidence of light on the photodiode PD. The same applies to the amplification transistor AMP and the dummy transistor. According to the present embodiment, these gate electrodes 24 are disposed periodically in the X direction and symmetrically in the Y direction, and thus such an effect can be obtained.

On the other hand, in four pixels 1 illustrated in A of FIG. 25, the photodiodes PD (n-type semiconductor region 12 and the p-type semiconductor region 13, and the like) in these pixels 1 are symmetrically disposed in the X direction and the Y direction. Therefore, since both the on-chip lens 17 and the photodiode PD have symmetrical shapes, it is possible to optimize the light collection efficiency and optical symmetry of these pixels 1.

Note that in the solid-state imaging device of the present embodiment, the upper left and upper right pixels 1 illustrated in A of FIG. 25 may share one on-chip lens 17, and the lower left and lower right pixels 1 illustrated in A of FIG. 25 may share the other on-chip lens 17.

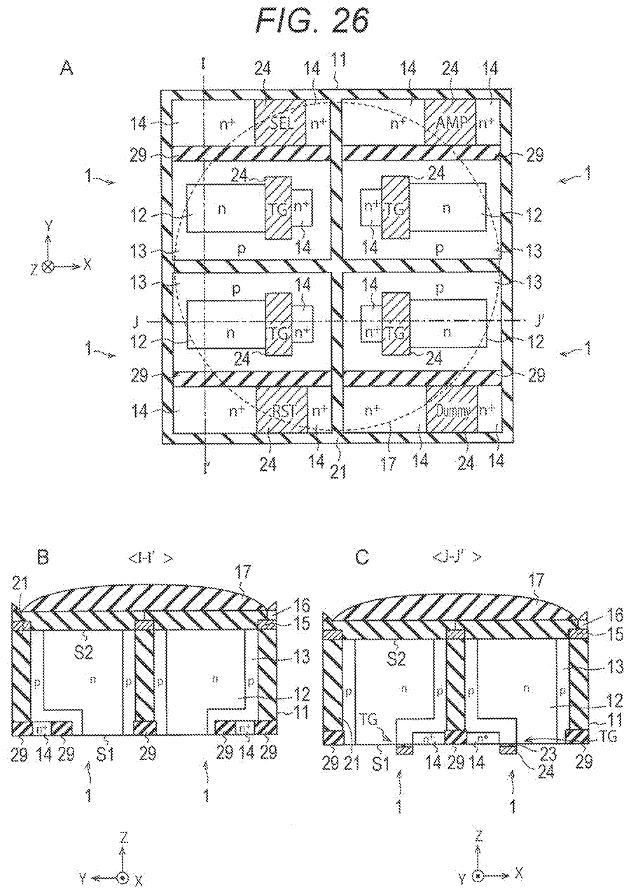

FIG. 26 illustrates a plan view and a cross-sectional view of a structure of the solid-state imaging device according to a modification example of the fourth embodiment.

The solid-state imaging device illustrated in A to C of FIG. 26 generally has the structure similar to that of the solid-state imaging device illustrated in A to C of FIG. 25. However, the on-chip lens 17 illustrated in A of FIG. 26 is provided in common on four pixels 1. Therefore, the effects similar to those of the solid-state imaging device illustrated in A to C of FIG. 25 can be obtained.

### Fifth Embodiment

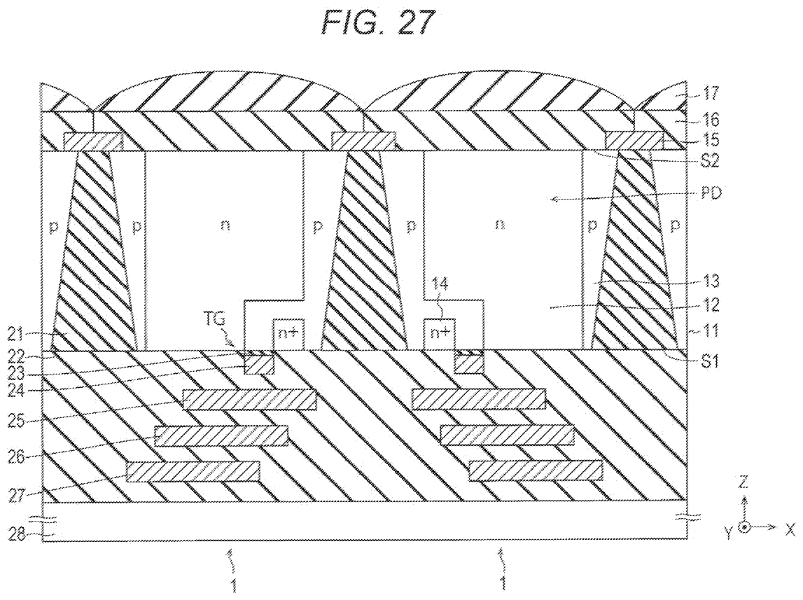

FIG. 27 is a cross-sectional view illustrating a structure of a solid-state imaging device according to the fifth embodiment. Similarly to FIG. 2, FIG. 27 illustrates a longitudinal cross section of two pixels 1 included in the pixel array 2.

As illustrated in FIG. 27, the side surface of the element isolation insulation film 21 of the present embodiment has a portion having a tapered shape. FIG. 27 Illustrates three portions as the element isolation insulation film 21, and side surfaces of the left portion, right portion, and center portion has tapered shapes. The central portion is located near the transfer transistor TG, and the left portion and the right portion are located far from the transfer transistor TG.

According to the present embodiment, the side surface of the element isolation insulation film 21 has the tapered shape, for example, a gradient of potential (transfer gradient) can be easily applied to the transfer transistor TG side. Therefore, the quantum efficiency (Qe) and the transfer gradient can be optimized.

Note that each portion as the element isolation insulation film 21 of the present embodiment may be provided on the element isolation insulation film 29 in a similar manner to the element isolation insulation film 21 illustrated in FIG. 3.

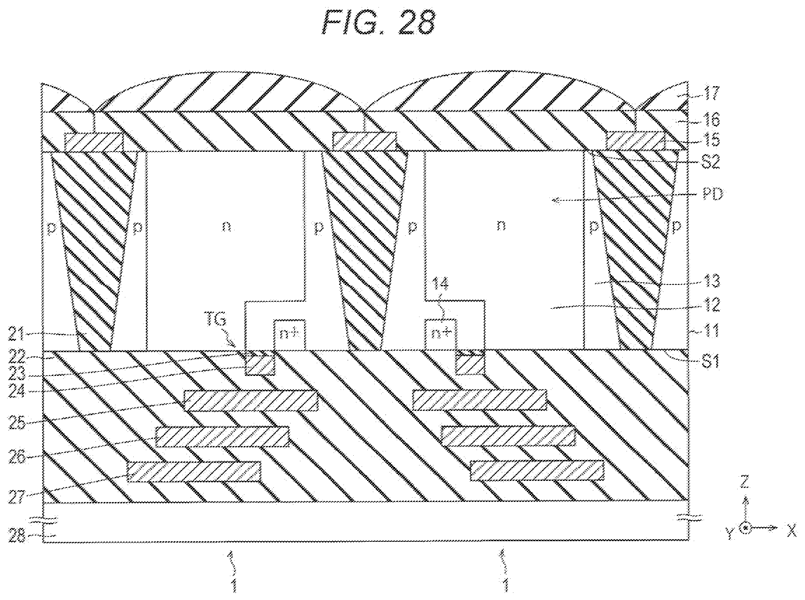

FIG. 28 is a cross-sectional view illustrating a structure of the solid-state imaging device according to a modification example of the fifth embodiment.

The solid-state imaging device illustrated in FIG. 28 generally has the structure similar to that of the solid-state imaging device illustrated in FIG. 27. However, the side surface of each portion as the element isolation insulation film 21 illustrated in FIG. 27 has a forward tapered shape, but the side surface of each portion as the element isolation insulation film 21 illustrated in FIG. 28 has a reverse tapered shape. As described above, the side surface of the element isolation insulation film 21 may has a portion having a forward tapered shape and/or may has a portion having a reverse tapered shape.

### Sixth Embodiment

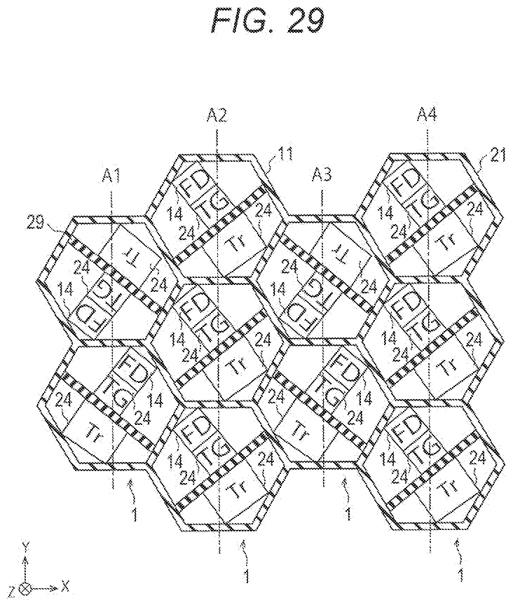

FIG. 29 is a plan view illustrating a structure of a solid-state imaging device according to the sixth embodiment.

FIG. 29 is a plan view illustrating ten pixels 1 included in the pixel array region 2, and illustrates a state in which these pixels 1 are viewed in a longitudinal direction. Each pixel 1 illustrated in FIG. 29 includes a gate electrode 24 of a transfer transistor TG, a gate electrode 24 of another transistor Tr, an n⁺-type semiconductor region 14 (floating diffusion portion FD), and an element isolation insulation film 29. Examples of the transistor Tr include a reset transistor RST, a selection transistor SEL, an amplification transistor AMP, and a dummy transistor. In FIG. 29, illustration of the n-type semiconductor region 12, the p-type semiconductor region 13, and the like is omitted.

Each pixel 1 of the present embodiment has a hexagonal shape in plan view. Therefore, each pixel 1 of the present embodiment has a honeycomb structure having a hexagonal column shape. Each pixel 1 illustrated in FIG. 29 has two sides parallel to the X direction and four sides inclined with respect to the X direction and the Y direction in plan view.

FIG. 29 illustrates four straight lines A1 to A4 parallel to the Y direction. FIG. 29 illustrates two pixels 1 located on the straight line A1, three pixels 1 located on the straight line A2, two pixels 1 located on the straight line A3, and three pixels 1 located on the straight line A4.

Three pixels 1 on the straight line A2 have a periodic structure in the Y direction. For example, the transfer transistor TG, transistor Tr, floating diffusion portion FD, and element isolation insulation film 29 in the upper pixel 1 on the straight line A2 are periodically disposed in the Y direction, respectively, with respect to the transfer transistor TG, transistor Tr, floating diffusion portion FD, and element isolation insulation film 29 in the central pixel 1 on the straight line A2. Therefore, the effects similar to those of the pixels 1 illustrated in FIG. 4 and the like can be obtained. The same applies to three pixels 1 on the straight line A4.

On the other hand, two pixels 1 on the straight line A1 have a structure that is rotationally symmetric to each other. For example, the transfer transistor TG, transistor Tr, floating diffusion portion FD, and element isolation insulation film 29 in the upper pixel 1 on the straight line A1 are disposed, respectively, at positions at which the transfer transistor TG, transistor Tr, floating diffusion portion FD, and element isolation insulation film 29 in the lower pixel 1 on the straight line A1 are rotated by 180 degrees. The same applies to two pixels 1 on the straight line A3.

Furthermore, the pixels 1 separated from each other in the X direction have a periodic structure in the X direction. For example, the transfer transistor TG, transistor Tr, floating diffusion portion FD, and element isolation insulation film 29 in the upper pixel 1 on the straight line A3 are periodically disposed in the X direction, respectively, with respect to the transfer transistor TG, transistor Tr, floating diffusion portion FD, and element isolation insulation film 29 in the upper pixel 1 on the straight line A1. Therefore, the effects similar to those of the pixels 1 illustrated in FIG. 13 and the like can be obtained. The same applies to a relationship between the pixels 1 on the straight line A2 and the pixels 1 on the straight line A4.

According to the present embodiment, the pixel 1 having the honeycomb structure is adopted, and thus it is possible to improve the degree of freedom in designing the layout of the components in each pixel 1. For example, a distance between the transistors Tr of the different pixels 1 can be increased. This is why there are only four corners at which the transistor Tr can be disposed in a case where the shape of each pixel 1 is a quadrangle, but there are six corners at which the transistor Tr can be disposed in a case where the shape of each pixel 1 is a hexagon. In FIG. 29, one corner of one pixel 1 is in contact with two corners of the other two pixels 1, but the transistor Tr is not disposed or only one transistor Tr is disposed near the contacts of these three corners.

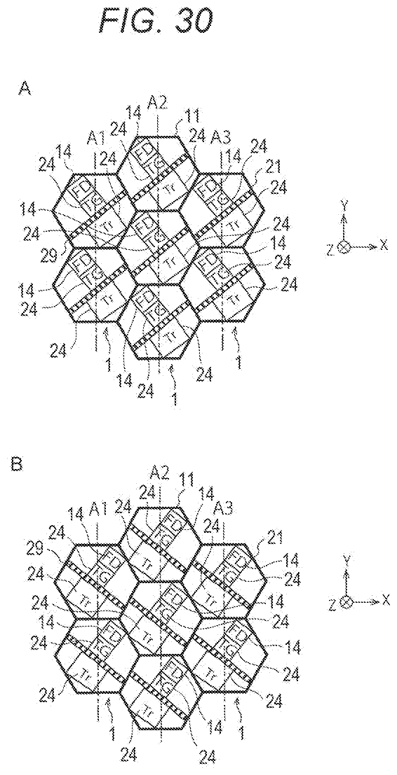

FIG. 30 is a plan view illustrating a structure of the solid-state imaging device according to a modification example of the sixth embodiment.

In the modification example of A of FIG. 30, all the pixels 1 have the same structure in plan view. Therefore, the pixels 1 on the same straight line among the straight lines A1 to A3 have a periodic structure in the Y direction. Similarly, the pixels 1 separated from each other in the X direction have a periodic structure in the X direction.

The same applies to the modification example of B of FIG. 30. In the modification example of B of FIG. 30, all the pixels 1 have the same structure in plan view. However, each pixel 1 illustrated in B of FIG. 30 has a line-symmetric structure with respect to each pixel 1 illustrated in A of FIG. 30.

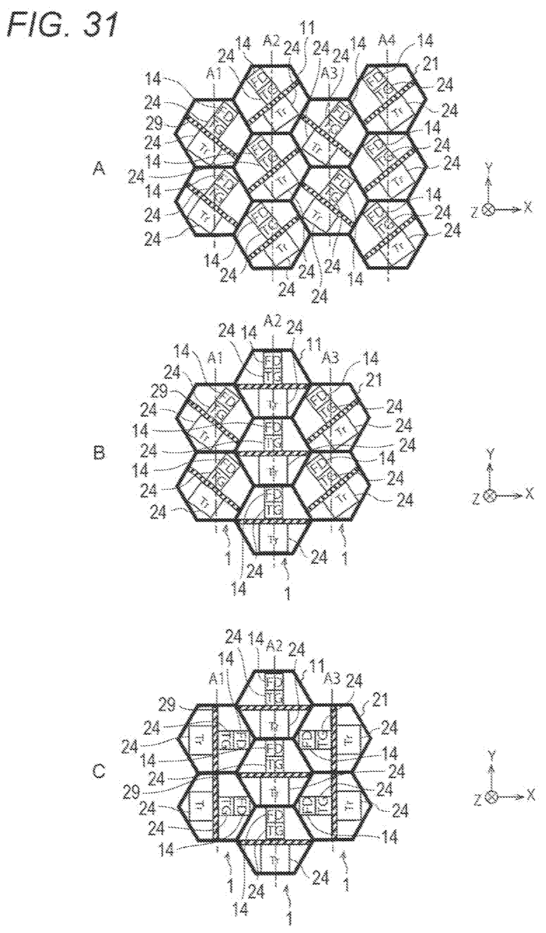

FIG. 31 is a plan view illustrating a structure of the solid-state imaging device according to another modification example of the sixth embodiment.

The solid-state imaging device illustrated in A of FIG. 31 has the structure similar to that of the solid-state imaging device illustrated in FIG. 29. However, in A of FIG. 31, two pixels 1 on the straight line A1 have a periodic structure in the Y direction, and two pixels 1 on the straight line A3 also have the periodic structure in the Y direction.

In the solid-state imaging device illustrated in B of FIG. 31, seven pixels 1 have a line-symmetric structure with respect to the straight line A2. Thus, each pixel 1 on the straight line A2 has a line-symmetric structure with respect to the straight line A2. Furthermore, the upper pixel 1 on the straight line A1 and the upper pixel 1 on the straight line A3 have a line-symmetric structure with respect to the straight line A2. Similarly, the lower pixel 1 on the straight line A1 and the lower pixel 1 on the straight line A3 have a line-symmetric structure with respect to the straight line A2.

The same applies to the solid-state imaging device illustrated in C of FIG. 31. In the solid-state imaging device illustrated in C of FIG. 31, seven pixels 1 have a line-symmetric structure with respect to the straight line A2. However, the structures of the pixels 1 on the straight lines A1 and A3 are different from those of B of FIG. 31 and C of FIG. 31.

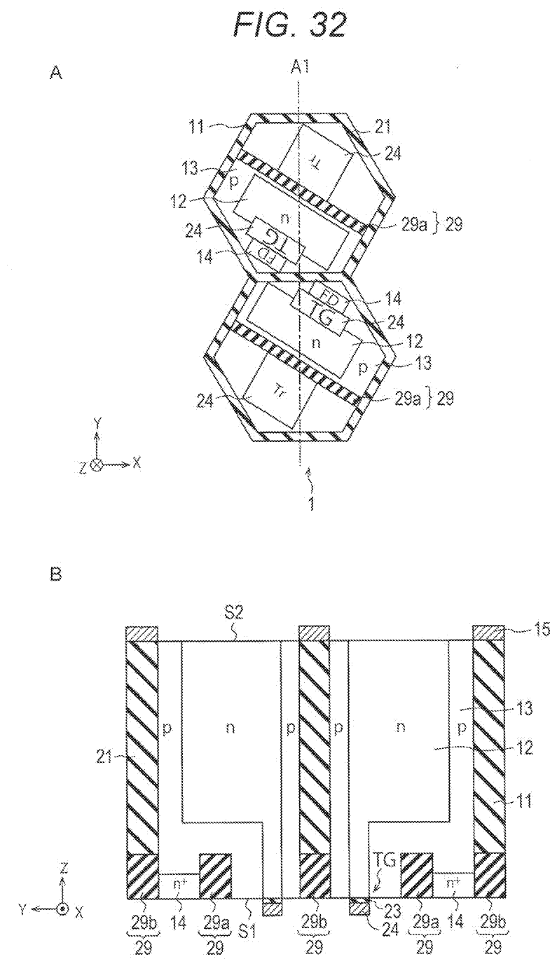

FIG. 32 is a plan view illustrating a structure of the solid-state imaging device according to another modification example of the sixth embodiment.

A of FIG. 32 corresponds to two pixels 1 on the straight line A1 illustrated in FIG. 29. Each pixel 1 of the present modification example also includes the element isolation insulation film 29 between the gate electrode 24 of the transfer transistor TG and the gate electrode 24 of the other transistor Tr in plan view. Note that the element isolation insulation film 29 illustrated in A of FIG. 32 is denoted by a reference sign 29a (internal element isolation insulation film) in order to be distinguished from an external element isolation insulation film 29b to be described later.

B of FIG. 32 illustrates a longitudinal cross section taken along the straight line A1 illustrated in A of FIG. 32. The element isolation insulation film 29 of the present modification example is disposed in each pixel 1 as described above, and is further disposed under the element isolation insulation film 21. The former element isolation insulation film 29 is indicated by a reference sign 29a (internal element isolation insulation film), and the latter element isolation insulation film 29 is indicated by a reference sign 29b (external element isolation insulation film).

### Seventh Embodiment

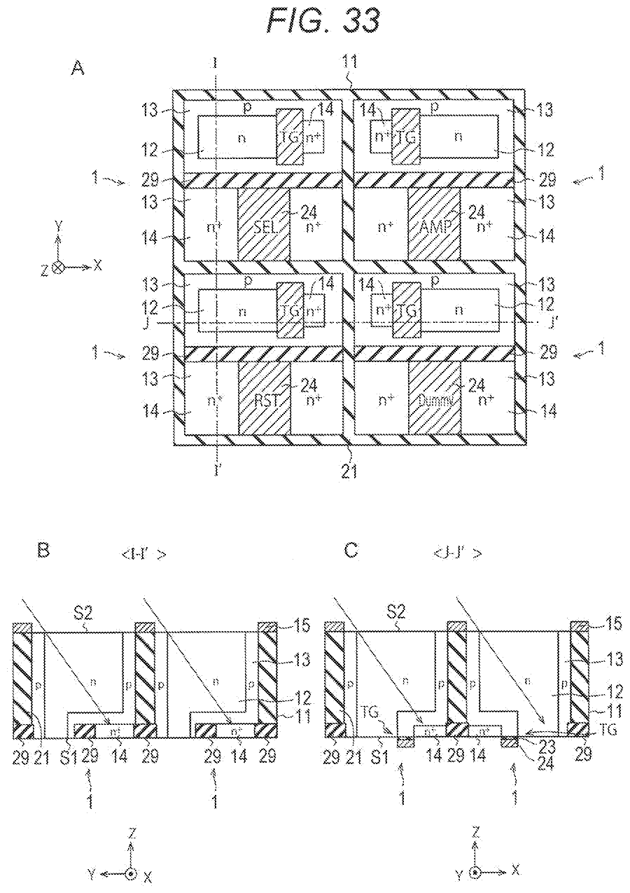

FIG. 33 illustrates a plan view and a cross-sectional view of a structure of a solid-state imaging device according to the seventh embodiment.

A of FIG. 33 is a plan view illustrating four pixels 1 included in the pixel array region 2, and illustrates a state in which these pixels 1 are viewed in a longitudinal direction. B of FIG. 33 illustrates a longitudinal cross section taken along line I-I′ illustrated in A of FIG. 25. C of FIG. 33 illustrates a longitudinal cross section taken along line J-J′ illustrated in A of FIG. 25.

The solid-state imaging device of the present embodiment generally has the structure similar to that of the solid-state imaging device of the first embodiment illustrated in A to C of FIG. 4. Thus, in the present embodiment, the corresponding components in two pixels 1 adjacent to each other in the X direction have a symmetrical structure in the X direction, and the corresponding components in two pixels 1 adjacent to each other in the Y direction generally have the periodic structure in the Y direction.

However, as illustrated in A of FIG. 33, each pixel 1 of the present embodiment includes the element isolation insulation film 29 on the symmetry plane of each pixel 1 perpendicular to the Y direction. That is, the element isolation insulation film 29 is provided on the XZ plane (on the symmetry plane) passing through an intermediate point between the side surface of each pixel 1 in the +Y direction and the side surface of each pixel 1 in the −Y direction. In plan view of each pixel 1, the element isolation insulation film 29 is provided between the gate electrode 24 of the transfer transistor TG and the gate electrode 24 of another transistor in each pixel 1.

As described above, each pixel 1 of the present embodiment includes the element isolation insulation film 29 on the symmetry plane of each pixel 1 perpendicular to the Y direction. Thus, the shape of the element isolation insulation film 29 in each pixel 1 is line-symmetric with respect to the symmetry plane described above. Therefore, it is possible to prevent the element isolation insulation film 29 from deteriorating the optical symmetry of each pixel 1.

### Eighth Embodiment

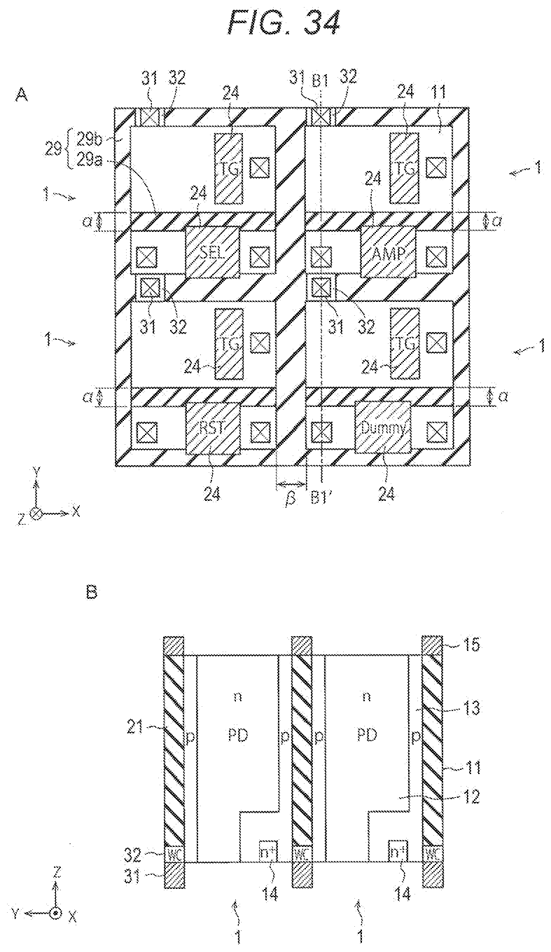

FIG. 34 illustrates a plan view and a cross-sectional view of a structure of a solid-state imaging device according to the eighth embodiment.

As in FIG. 24, A of FIG. 34 is a plan view illustrating four pixels 1 included in the pixel array region 1, and illustrates a state in which these pixels 1 are viewed in a longitudinal direction. Each pixel 1 includes the gate electrode 24 of transfer transistor TG and the gate electrode 24 of another transistor (reset transistor RST, the selection transistor SEL, the amplification transistor AMP, or the dummy transistor). A of FIG. 34 further illustrates element isolation insulation films 21 surrounding these pixels 1, a plurality of well contact regions 32, a plurality of contact plugs 31 provided under these well contact regions 32, and the like. Each of the well contact regions 32 illustrated in A of FIG. 34 is provided for the pixel 1 illustrated in A of FIG. 34, and is provided under the element isolation insulation film 21. Note that the widths of the element isolation insulation films 29 illustrated in A of FIG. 34 are all a.

B of FIG. 34 illustrates a simplified longitudinal cross section taken along the straight line B1 illustrated in A of FIG. 33. B of FIG. 34 illustrates three well contact (WC) region 32 provided under the element isolation insulation films 21 and three contact plugs 31 provided under these well contact regions 32.

The well contact region 32 is a semiconductor region provided in the substrate 11. The well contact region 32 is, for example, a p-type semiconductor region. Furthermore, each of the contact plugs 31 illustrated in B of FIG. 34 is provided on the front surface S1 of the substrate 11, and more specifically, is provided under the corresponding well contact region 32. The well contact region 32 and contact plug 31 of the present embodiment are provided at a position overlapping the element isolation insulation film 21 in plan view.

The contact plug 31 illustrated in B of FIG. 34 is used to supply a fixed potential to the substrate 11. More specifically, the contact plug 31 illustrated in B of FIG. 34 supplies the fixed potential to a well in the substrate 11 via the well contact region 32. Therefore, the potential of the well in the substrate 11 can be set to the fixed potential. The contact plug 31 illustrated in B of FIG. 34 is, for example, electrically connected to the wiring layers 25 to 27 illustrated in FIG. 2 and the like, and supplies the fixed potential from the wirings 25 to 27.

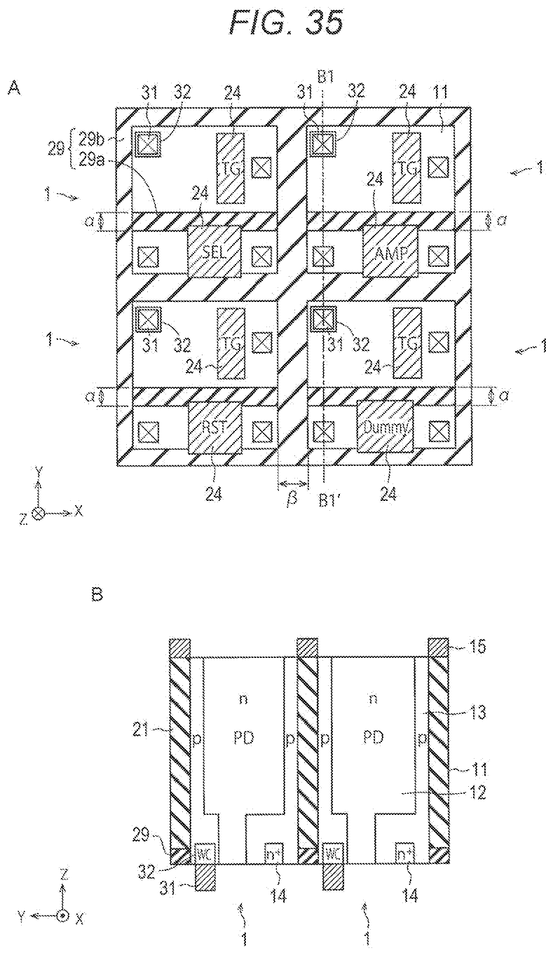

FIG. 35 illustrates a plan view and a cross-sectional view of a structure of the solid-state imaging device according to a comparative example of the eighth embodiment.

A and B in FIG. 35 correspond to A and B in FIG. 34, respectively. As illustrated in A and B of FIG. 35, the well contact region 32 of the present comparative example is disposed not under the element isolation insulation film 21 but in each pixel 1. Furthermore, the contact plug 31 for the well contact region 32 of the present comparative example is provided under the corresponding well contact region 32 as illustrated in A and B of FIG. 35.

When the well contact region 32 is disposed in the pixel 1 as in the present comparative example, there is a possibility that the size of the photodiode PD is reduced due to the well contact region 32. As a result, there is a possibility that the photoelectric conversion efficiency of each pixel 1 decreases.

On the other hand, the well contact region 32 and the corresponding contact plug 31 of the present embodiment are provided under the element isolation insulation film 21. Therefore, it is possible to prevent the size of the photodiode PD from being reduced due to the well contact region 32. Thus, according to the present embodiment, the photoelectric conversion efficiency of each pixel 1 can be improved.

Note that the well contact region 32 illustrated in A of FIG. 34 is provided under the straight line portion of the element isolation insulation film 21, and thus it can be shared by two pixels 1. The well contact region 32 may be provided under the intersection portion of the element isolation insulation films 21. Therefore, the well contact region 32 can be shared by four pixels 1.

### Ninth Embodiment

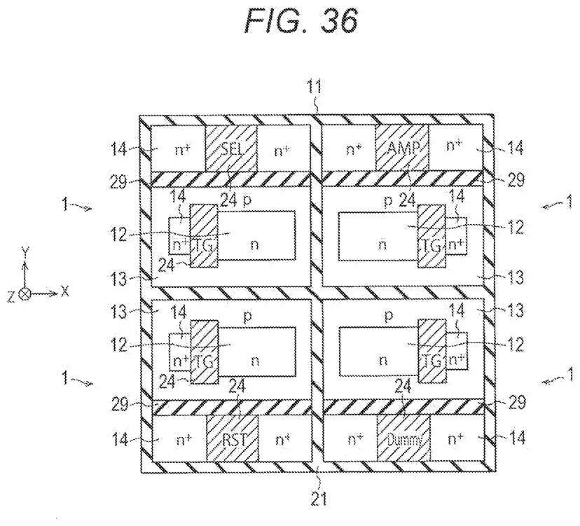

FIG. 36 is a plan view illustrating a structure of a solid-state imaging device according to the ninth embodiment.

FIG. 36 is a plan view illustrating four pixels 1 included in the pixel array region 2, and illustrates a state in which these pixels 1 are viewed in a longitudinal direction. The solid-state imaging device of the present embodiment generally has the structure similar to that of the solid-state imaging device of the comparative example of the first embodiment illustrated in A of FIG. 5. Thus, in the present embodiment, the corresponding components in two pixels 1 adjacent to each other in the X direction have a symmetrical structure in the X direction, and the corresponding components in two pixels 1 adjacent to each other in the Y direction have the symmetrical structure in the Y direction.

However, in the upper left pixel 1 and upper right pixel 1 illustrated in FIG. 36, the n-type semiconductor regions 12 of these pixels 1 face each other. Therefore, the n-type semiconductor regions 12 in these pixels 1 include a portion interposed between the gate electrode 24 of the transfer transistor TG in the upper left pixel 1 and the gate electrode 24 of the transfer transistor TG in the upper right pixel 1 in plan view. In other words, the n-type semiconductor region 12 in the upper left pixel 1 exists on the right side of the gate electrode 24 of the transfer transistor TG in the upper left pixel 1, and the n-type semiconductor region 12 in the upper right pixel 1 exists on the left side of the gate electrode 24 of the transfer transistor TG in the upper right pixel 1. The same applies to the lower left pixel 1 and lower right pixel 1 illustrated in FIG. 36.

Four pixels 1 illustrated in FIG. 36 share the reset transistor RST, selection transistor SEL, and amplification transistor AMP in these pixels 1. In the present embodiment, the n-type semiconductor regions 12 of these pixels 1 face each other in the X direction. Thus, according to the present embodiment, the photoelectric conversion efficiency of the solid-state imaging device can be improved.

Note that the structures of the n-type semiconductor region 12 and transfer transistor TG illustrated in FIG. 36 may be applied to any of the solid-state imaging devices of the first to eighth embodiments instead of being applied to the solid-state imaging device of the comparative example of the first embodiment.

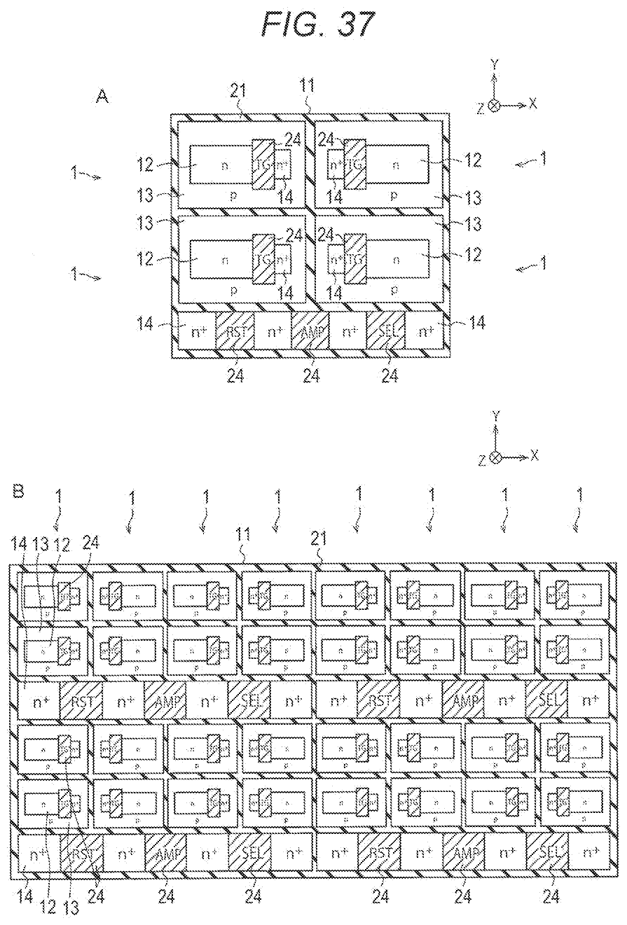

FIG. 37 is a plan view illustrating a structure of the solid-state imaging device according to a modification example of the ninth embodiment.

In the modification example of A of FIG. 37, four pixels 1 have a structure symmetrical in the X direction and a periodic structure in the Y direction. Thus, the corresponding components in two pixels 1 adjacent to each other in the X direction have a symmetrical structure in the X direction, and the corresponding components in two pixels 1 adjacent to each other in the Y direction have the periodic structure in the Y direction.

A of FIG. 37 illustrates the reset transistor RST, selection transistor SEL, and amplification transistor AMP shared by these pixels 1. In the present modification example, the reset transistor RST, the selection transistor SEL, and the amplification transistor AMP are not in these pixels 1, but disposed in a line in the −Y direction of these pixels 1. According to the present modification example, by collectively disposing the reset transistor RST, the selection transistor SEL, and the amplification transistor AMP outside these pixels 1, or without disposing the dummy transistor, it is possible to improve the integration degree of the solid-state imaging device. The reset transistor RST, selection transistor SEL, and amplification transistor AMP of the present modification example are disposed symmetrically in the X direction as illustrated in A of FIG. 37. According to the present modification example, it is possible to reduce noise of these transistors by increasing a running length.

B of FIG. 37 illustrates 32 pixels 1 divided into four groups. In each group, eight pixels 1 have a symmetrical structure in the X direction and a periodic structure in the Y direction, and share the reset transistor RST, the selection transistor SEL, and the amplification transistor AMP. These transistors are disposed in a line in the −Y direction of these pixels 1, not in these pixels 1. According to the present modification example, by collectively disposing the reset transistor RST, the selection transistor SEL, and the amplification transistor AMP outside these pixels 1, or without disposing the dummy transistor, it is possible to improve the integration degree of the solid-state imaging device.

### Application Example

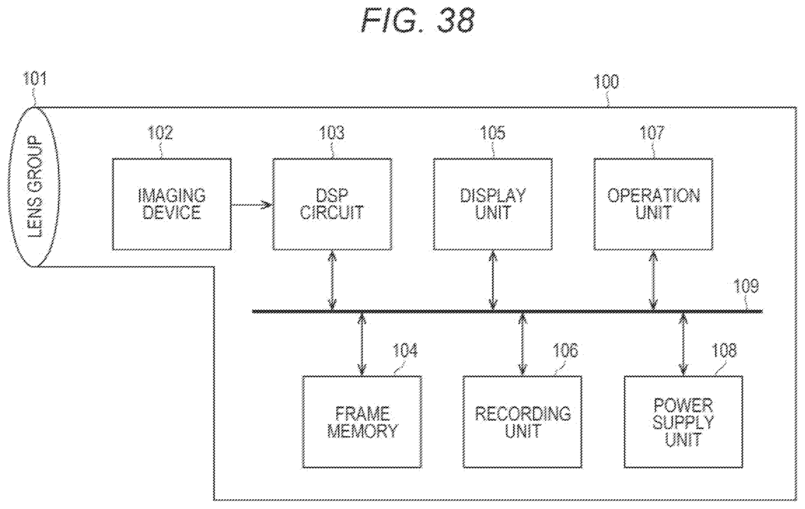

FIG. 38 is a block diagram illustrating a configuration example of an electronic apparatus. The electric apparatus illustrated in FIG. 38 is a camera 100.

The camera 100 includes an optical unit 101 including a lens group, an imaging device 102 which is the solid-state imaging device according to any one of the first to ninth embodiments, a digital signal processor (DSP) circuit 103 which is a camera signal processing circuit, a frame memory 104, a display unit 105, a recording unit 106, an operation unit 107, and a power supply unit 108. Furthermore, the DSP circuit 103, the frame memory 104, the display unit 105, the recording unit 106, the operation unit 107, and the power supply unit 108 are connected to each other via a bus line 109.

The optical unit 101 receives incident light (image light) from a subject and forms an image on an imaging surface of the imaging device 102. The imaging device 102 converts the light amount of the incident light imaged on the imaging surface by the optical unit 101 into an electrical signal in units of pixels, and outputs the electrical signal as a pixel signal.

The DSP circuit 103 performs signal processing on the pixel signal output by the imaging device 102. The frame memory 104 is a memory for storing one screen of a moving image or a still image, which is captured by the imaging device 102.

The display unit 105 includes, for example, a display device of a panel type such as a liquid crystal panel type or an organic EL panel type, and displays the moving image or the still image, which is captured by the imaging device 102. The recording unit 106 records the moving image or the still image, which is captured by the imaging device 102 on a recording medium such as a hard disk or a semiconductor memory.

The operation unit 107 issues operation commands for various functions of the camera 100 under operation by a user. The power supply unit 108 appropriately supplies various power sources as operation power sources of the DSP circuit 103, the frame memory 104, the display unit 105, the recording unit 106, and the operation unit 107 to these power supply targets.

In a case where the solid-state imaging device according to any one of the first to ninth embodiments is used as the imaging device 102, a good image can be expected to be acquired.

The solid-state imaging device can be applied to various other products. For example, the solid-state imaging device may be mounted on any type of mobile body such as an automobile, an electric vehicle, a hybrid electric vehicle, a motorcycle, a bicycle, a personal mobility, an airplane, a drone, a ship, or a robot.

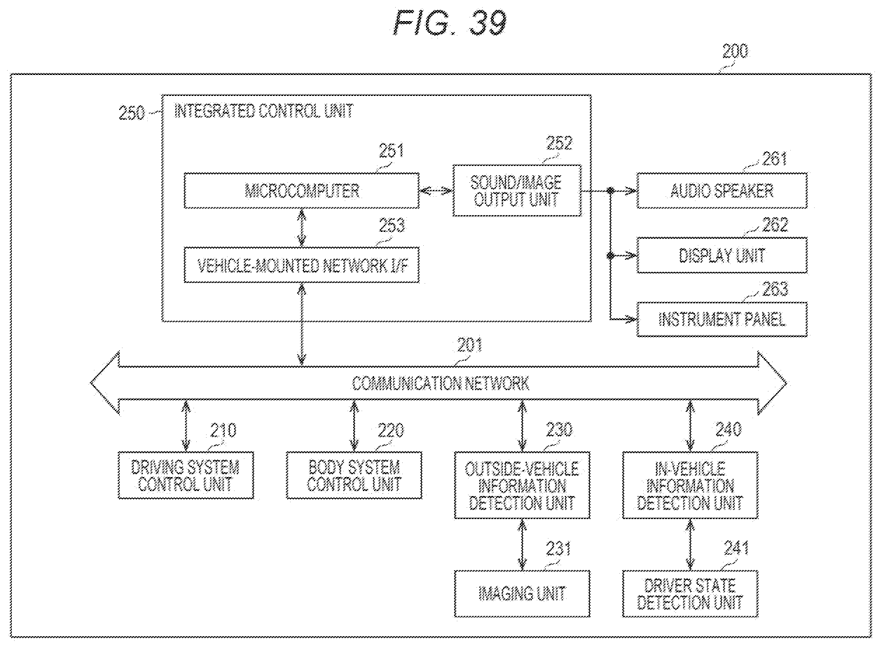

FIG. 39 is a block diagram illustrating a configuration example of a mobile body control system. The mobile body control system illustrated in FIG. 39 is a vehicle control system 200.

The vehicle control system 200 includes a plurality of electronic control units connected to each other via a communication network 201. In the example illustrated in FIG. 39, the vehicle control system 200 includes a driving system control unit 210, a body system control unit 220, an outside-vehicle information detection unit 230, an in-vehicle information detection unit 240, and an integrated control unit 250. Moreover, in FIG. 39, a microcomputer 251, a sound/image output unit 252, and a vehicle-mounted network interface (FF) 253 are illustrated as configurations of the integrated control unit 250.

The driving system control unit 210 controls the operation of devices related to the driving system of the vehicle in accordance with various kinds of programs. For example, the driving system control unit 210 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 220 controls the operation of various kinds of devices provided to a vehicle body in accordance with various kinds of programs. For example, the body system control unit 220 functions as a control device for a smart key system, a keyless entry system, a power window device, or various kinds of lamps (for example, a headlamp, a backup lamp, a brake lamp, a turn signal lamp, a fog lamp). In this case, radio waves transmitted from a mobile device as an alternative to a key or signals of various kinds of switches can be input to the body system control unit 220. The body system control unit 220 receives these input radio waves or signals, and controls a door lock device, the power window device, the lamps, or the like of the vehicle.

The outside-vehicle information detection unit 230 detects information regarding the outside of the vehicle including the vehicle control system 200. For example, the imaging unit 231 is connected to the outside-vehicle information detection unit 230. The outside-vehicle information detection unit 230 makes the imaging unit 231 form an image of the outside of the vehicle, and receives the captured image from the imaging unit 231. On the basis of the received image, the outside-vehicle information detection unit 230 may perform processing of detecting an object such as a human, a vehicle, an obstacle, a sign, a character on a road surface, or the like, or processing of detecting a distance thereto.

The imaging unit 231 is an optical sensor that receives light and outputs an electric signal corresponding to a received light amount of the light. The imaging unit 231 can output the electric signal as an image, or can output the electric signal as information regarding a measured distance. The light received by the imaging unit 231 may be visible light, or may be invisible light such as infrared rays or the like. The imaging unit 231 includes the solid-state imaging device according to any one of the first to ninth embodiments.

The in-vehicle information detection unit 240 detects information regarding the inside of the vehicle including the vehicle control system 200. The in-vehicle information detection unit 240 is, for example, connected to a driver state detection unit 241 that detects the state of a driver. For example, the driver state detection unit 241 includes a camera that images the driver. On the basis of detection information input from the driver state detection unit 241, the in-vehicle information detection unit 240 may calculate a degree of fatigue of the driver or a degree of concentration of the driver, or may determine whether the driver is dozing. The camera may include the solid-state imaging device according to any one of the first to ninth embodiments, and may be, for example, the camera 100 illustrated in FIG. 38.

The microcomputer 251 can calculate a control target value for the driving force generation device, the steering mechanism, or the braking device on the basis of information regarding the inside or outside of the vehicle, the information obtained by the outside-vehicle information detection unit 230 or the in-vehicle information detection unit 240, and output a control command to the driving system control unit 210. For example, the microcomputer 251 can perform cooperative control intended to implement functions of an advanced driver assistance system (ADAS) which performs collision avoidance or shock mitigation for the vehicle, following driving based on a following distance, vehicle speed maintaining driving, a warning of collision, a warning of deviation from a lane, or the like.

Furthermore, the microcomputer 251 can perform cooperative control intended for automated driving, which makes the vehicle to travel in an automated manner without depending on the operation of the driver, or the like, by controlling the driving force generation device, the steering mechanism, or the braking device on the basis of information regarding the periphery of the vehicle, the information obtained by the outside-vehicle information detection unit 230 or the in-vehicle information detection unit 240.

Furthermore, the microcomputer 251 can output a control command to the body system control unit 220 on the basis of information regarding the outside of the vehicle, the information obtained by the outside-vehicle information detection unit 230. For example, the microcomputer 251 can perform cooperative control intended to prevent a glare by controlling the headlamp so as to change from a high beam to a low beam, for example, in accordance with the position of a preceding vehicle or an oncoming vehicle, which is detected by the outside-vehicle information detection unit 230.

The sound/image output unit 252 transmits an output signal of at least one of a sound or an image to an output device capable of visually or auditorily notifying an occupant of the vehicle or the outside of the vehicle of information. In the example of FIG. 39, an audio speaker 261, a display unit 262, and an instrument panel 263 are illustrated as the output device. For example, the display unit 262 may include an on-board display or a head-up display.

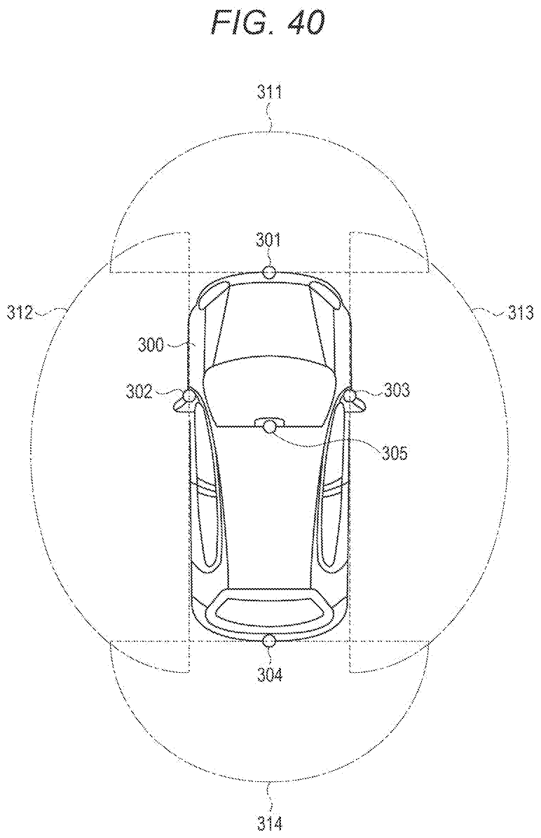

FIG. 40 is a plan view illustrating a specific example of a setting position of the imaging unit 231 of FIG. 39.

A vehicle 300 illustrated in FIG. 40 includes, as the imaging unit 231, imaging units 301, 302, 303, 304, and 305. The imaging units 301, 302, 303, 304, and 305 are, for example, provided at positions on a front nose, sideview mirrors, a rear bumper, and a back door of the vehicle 300 and at a position on an upper portion of a windshield inside the vehicle interior.

The imaging unit 301 provided on the front nose mainly acquires an image of a forward side of the vehicle 300. The imaging unit 302 provided on a left sideview mirror and the imaging unit 303 provided on a right sideview mirror mainly acquire an image of the sideward side of the vehicle 300. The imaging unit 304 provided on the rear bumper or the back door mainly acquires an image of the rearward side of the vehicle 300. The imaging unit 305 provided on an upper portion of the windshield inside the vehicle interior mainly acquires an image of the forward side of the vehicle 300. The imaging unit 305 is used to detect, for example, a preceding vehicle, a pedestrian, an obstacle, a traffic light, a traffic sign, a lane, and the like.

FIG. 40 illustrates an example of imaging ranges of the imaging units 301, 302, 303, and 304 (hereinafter, referred to as “imaging units 301 to 304”). An imaging range 311 indicates an imaging range of the imaging unit 301 provided on the front nose. An imaging range 312 indicates an imaging range of the imaging unit 302 provided on the left sideview mirror. An imaging range 313 indicates an imaging range of the imaging unit 303 provided on the right sideview mirror. An imaging range 314 indicates an imaging range of the imaging unit 304 provided on the rear bumper or the back door. For example, a bird's-eye image of the vehicle 300 as viewed from above is obtained by superimposing image data captured by the imaging units 301 to 304. Hereinafter, the imaging ranges 311, 312, 313, and 314 are referred to as “imaging ranges 311 to 314”.

At least one of the imaging units 301 to 304 may have a function of obtaining distance information. For example, at least one of the imaging units 301 to 304 may be a stereo camera including a plurality of imaging devices, or may be an imaging device having pixels for phase difference detection.

For example, the microcomputer 251 (FIG. 39) calculates a distance to each three-dimensional object in the imaging ranges 311 to 314 and a temporal change in distance (relative speed with respect to the vehicle 300) on the basis of distance information obtained from the imaging units 301 to 304. On the basis of these calculation results, the microcomputer 251 can extract, as a preceding vehicle, a closest three-dimensional object on a traveling path of the vehicle 300, the object traveling at a predetermined speed (for example, 0 km/h or more) in substantially the same direction as that of the vehicle 300. Moreover, the microcomputer 251 can set a following distance to be maintained in front of a preceding vehicle in advance, and perform automatic brake control (including following stop control), automatic acceleration control (including following start control), or the like. According to this example, it is possible to perform cooperative control intended for automated driving that makes the vehicle travel automatedly without depending on the operation of the driver or the like.

For example, the microcomputer 251 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging units 301 to 304, extract the classified three-dimensional object data, and use the extracted three-dimensional object data for automatic avoidance of an obstacle. For example, the microcomputer 251 identifies obstacles around the vehicle 300 as obstacles that the driver of the vehicle 300 can recognize visually and obstacles that are difficult for the driver of the vehicle 300 to recognize visually. Then, the microcomputer 251 determines a collision risk indicating the degree of a risk of collision with each obstacle. In a situation in which the collision risk is equal to or higher than a set value and thus there is a possibility of collision, the microcomputer 251 outputs a warning to the driver via the audio speaker 261 or the display unit 262, and performs forced deceleration or avoidance steering via the driving system control unit 210. In this manner, the microcomputer 251 can assist in driving to avoid the collision.

At least one of the imaging units 301 to 304 may be an infrared camera that detects infrared rays. For example, the microcomputer 251 determines whether or not there is a pedestrian in images captured by the imaging units 301 to 304, and thus the pedestrian can be recognized. Such recognition of the pedestrian is performed, for example, by a procedure of extracting feature points in the images captured by the imaging units 301 to 304 as infrared cameras and a procedure of determining whether or not it is the pedestrian by performing pattern matching processing on a series of feature points representing the contour of the object. When the microcomputer 251 determines that there is the pedestrian in the images captured by the imaging units 301 to 304, and thus recognizes the pedestrian, the sound/image output unit 252 controls the display unit 262 such that a square contour line for emphasis is displayed on the recognized pedestrian in a superimposing manner. Furthermore, the sound/image output unit 252 may control the display unit 262 such that an icon or the like indicating a pedestrian is displayed at a desired position.

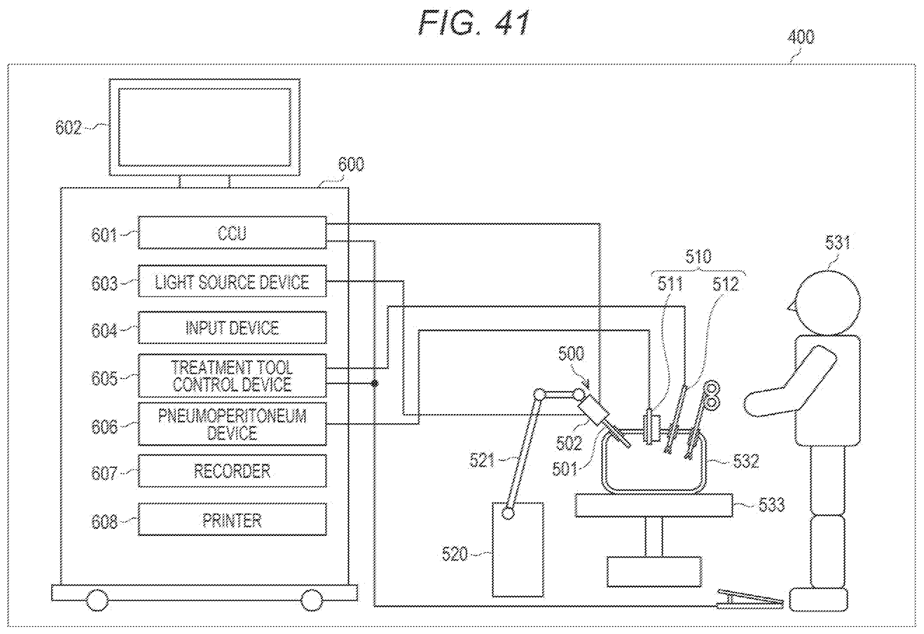

FIG. 41 is a diagram illustrating an example of a schematic configuration of an endoscopic surgery system to which the technology according to the present disclosure (the present technology) can be applied.

FIG. 41 illustrates a state in which an operator (medical doctor) 531 is performing surgery on a patient 532 on a patient bed 533 by using an endoscopic surgery system 400. As illustrated in FIG. 41, the endoscopic surgery system 400 includes an endoscope 500, other surgical tools 510 such as a pneumoperitoneum tube 511 and an energy treatment tool 512, a support arm device 520 that supports the endoscope 500, and a cart 600 on which various devices for endoscopic surgery are mounted.

The endoscope 500 includes a lens barrel 501 of which a region having a predetermined length from the distal end is inserted into the body cavity of the patient 532, and a camera head 502 connected to the base end of the lens barrel 501. In the illustrated example, the endoscope 500 configured as a so-called rigid scope having the rigid lens barrel 501 is illustrated, but the endoscope 500 may be configured as a so-called flexible scope having a flexible lens barrel.

An opening portion into which an objective lens is fitted is provided at the distal end of the lens barrel 501. A light source device 603 is connected to the endoscope 500, and light generated by the light source device 603 is guided to the distal end of the lens barrel by a light guide extending inside the lens barrel 501, and is emitted toward an observation target in the body cavity of the patient 532 via the objective lens. Note that the endoscope 500 may be a forward-viewing endoscope, an oblique-viewing endoscope, or a side-viewing endoscope.

An optical system and an imaging element are provided inside the camera head 502, and reflected light (observation light) from the observation target is condensed on the imaging element by the optical system. The observation light is photoelectrically converted by the imaging element, and an electric signal corresponding to the observation light, that is, an image signal corresponding to the observation image is generated. The image signal as RAW data is transmitted to a camera control unit (CCU) 601.

The CCU 601 includes a central processing unit (CPU) and a graphics processing unit (GPU), and integrally controls operations of the endoscope 500 and the display device 602. Moreover, the CCU 601 receives an image signal from the camera head 502, and performs various image processing for displaying an image based on the image signal, such as development processing (demosaic processing), on the image signal.

The display device 602 displays an image based on the image signal subjected to the image processing by the CCU 601 under the control of the CCU 601.

For example, the light source device 603 includes a light source such as a light emitting diode (LED) and supplies irradiation light for imaging a surgical site or the like to the endoscope 500.

An input device 604 is an input interface for the endoscopic surgery system 11000. A user can input various types of information and instructions to the endoscopic surgery system 400 via the input device 604. For example, the user inputs an instruction or the like to change imaging conditions (type, magnification, focal length, and the like of irradiation light) by the endoscope 500.

A treatment tool control device 605 controls driving of the energy treatment tool 512 for cauterization and incision of tissue, sealing of a blood vessel, or the like. A pneumoperitoneum device 606 feeds gas into the body cavity of the patient 532 via the pneumoperitoneum tube 511 in order to inflate the body cavity of the patient 532 for the purpose of securing a visual field of the endoscope 500 and securing a working space of the operator. A recorder 607 is a device capable of recording various types of information regarding surgery. A printer 608 is a device capable of printing various types of information regarding surgery in various formats such as text, image, or graph.

Note that the light source device 603 that supplies the endoscope 500 with the irradiation light at the time of imaging the surgical site may include, for example, an LED, a laser light source, or a white light source including a combination thereof. In a case where the white light source includes a combination of RGB laser light sources, the output intensity and output timing of each color (each wavelength) can be controlled with high accuracy, and thus adjustment of the white balance of the captured image can be performed in the light source device 603. Furthermore, in this case, the observation target is irradiated with laser light from each of the RGB laser light sources in a time division manner, and driving of the imaging element of the camera head 502 is controlled in synchronization with an irradiation timing. Therefore, it is also possible to capture an image corresponding to each of RGB in a time division manner. In this method, a color image can be obtained without providing a color filter on the imaging element.

Furthermore, the driving of the light source device 603 may be controlled so as to change the intensity of light to be output every predetermined time. Since the driving of the imaging element of the camera head 502 is controlled in synchronization with the timing of the change of the light intensity to acquire images in a time division manner and the images are synthesized, it is possible to generate an image of a high dynamic range without so-called black defects and halation.

Furthermore, the light source device 603 may be configured to be capable of supplying light in a predetermined wavelength band corresponding to special light imaging. In the special light imaging, by using wavelength dependency of light absorption in a body tissue, for example, so-called narrow band imaging is performed in which a predetermined tissue such as a blood vessel in a mucous membrane surface layer is imaged with high contrast by radiating light in a narrower band as compared with irradiation light (that is, white light) at the time of normal imaging. Alternatively, in the special light imaging, fluorescence imaging for obtaining an image with fluorescence generated by irradiation with excitation light may be performed. In the fluorescence imaging, it is possible to irradiate a body tissue with excitation light to observe fluorescence from the body tissue (Auto-Fluorescence Imaging), or to locally inject a reagent such as indocyanine green (ICG) into the body tissue and irradiate the body tissue with excitation light corresponding to a fluorescence wavelength of the reagent to obtain a fluorescent image. The light source device 603 can be configured to be capable of supplying narrow band light and/or excitation light corresponding to such special light imaging.

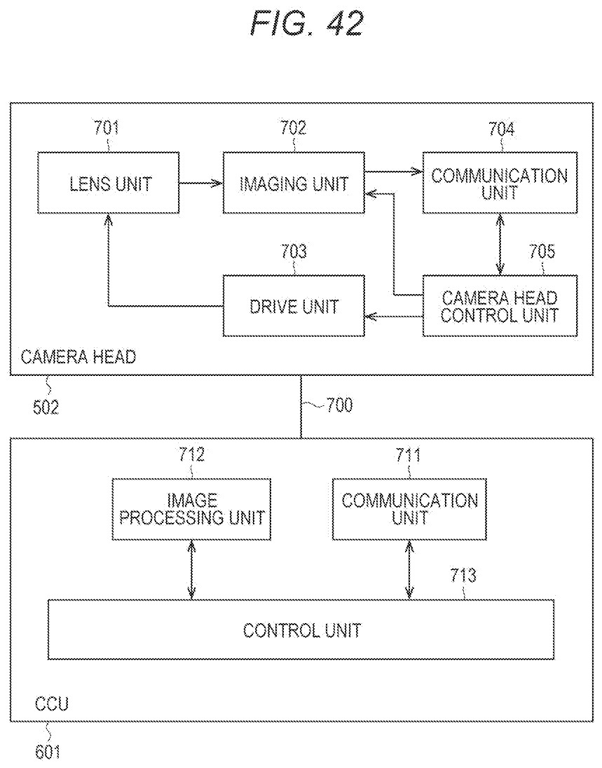

FIG. 42 is a block diagram illustrating an example of functional configurations of the camera head 502 and CCU 601 illustrated in FIG. 41.

The camera head 502 includes a lens unit 701, an imaging unit 702, a drive unit 703, a communication unit 704, and a camera head control unit 705. The CCU 601 includes a communication unit 711, an image processing unit 712, and a control unit 713. The camera head 502 and the CCU 601 are communicably connected to each other by a transmission cable 700.

The lens unit 701 is an optical system provided at a connection portion with the lens barrel 501. Observation light taken in from the distal end of the lens barrel 501 is guided to the camera head 502 and enters the lens unit 701. The lens unit 701 is configured by combining a plurality of lenses including a zoom lens and a focus lens.

The imaging unit 702 includes an imaging element. The number of imaging elements constituting the imaging unit 702 may be one (so-called single-plate type) or plural (so-called multi-plate type). In a case where the imaging unit 702 is configured as a multi-plate type imaging unit, for example, an image signal corresponding to each RGB may be generated by each imaging element, and a color image may be obtained by combining the image signals. Alternatively, the imaging unit 702 may include a pair of imaging elements for acquiring right-eye and left-eye image signals corresponding to three-dimensional (3D) display. By performing the 3D display, the operator 531 can more accurately recognize the depth of the living tissue in the surgical site. Note that, in a case where the imaging unit 702 is configured as a multi-plate type imaging unit, a plurality of lens units 701 can be provided corresponding to the imaging elements. The imaging unit 702 is the solid-state imaging device according to any one of the first to ninth embodiments.

Furthermore, the imaging unit 702 may not be necessarily provided in the camera head 502. For example, the imaging unit 702 may be provided immediately after the objective lens inside the lens barrel 501.

The drive unit 703 includes an actuator, and moves the zoom lens and focus lens of the lens unit 701 by a predetermined distance along an optical axis under the control of the camera head control unit 705. Therefore, the magnification and focus of the image captured by the imaging unit 702 can be appropriately adjusted.

The communication unit 704 includes a communication device for transmitting and receiving various types of information to and from the CCU 601. The communication unit 704 transmits, as RAW data, the image signal obtained from the imaging unit 702 to the CCU 601 via the transmission cable 700.

Furthermore, the communication unit 704 receives a control signal for controlling driving of the camera head 502 from the CCU 601, and supplies the control signal to the camera head control unit 705. The control signal includes information regarding imaging conditions, for example, information for specifying a frame rate of a captured image, information for specifying an exposure value at the time of imaging, and/or information for specifying magnification and focus of a captured image.

Note that the imaging conditions such as the frame rate, the exposure value, the magnification, and the focus may be appropriately specified by the user, or may be automatically set by the control unit 713 of the CCU 601 on the basis of the acquired image signal. In the latter case, a so-called auto exposure (AE) function, an auto focus (AF) function, and an auto white balance (AWB) function are installed in the endoscope 500.

The camera head control unit 705 controls driving of the camera head 502 on the basis of the control signal received from the CCU 601 via the communication unit 704.

The communication unit 711 includes a communication device for transmitting and receiving various types of information to and from the camera head 502. The communication unit 711 receives an image signal transmitted from the camera head 502 via the transmission cable 700.

Furthermore, the communication unit 711 transmits the control signal for controlling driving of the camera head 502 to the camera head 502. The image signal and the control signal can be transmitted by electric communication, optical communication, or the like.

The image processing unit 712 performs various image processing on the image signal that is RAW data transmitted from the camera head 502.

The control unit 713 performs various control related to imaging of a surgical site or the like by the endoscope 500 and display of a captured image obtained by imaging of the surgical site. For example, the control unit 713 generates a control signal for controlling driving of the camera head 502.

Furthermore, the control unit 713 causes the display device 602 to display the captured image showing a surgical site or the like on the basis of the image signal subjected to the image processing by the image processing unit 712. At this time, the control unit 713 may recognize various objects in the captured image by using various image recognition technologies. For example, the control unit 713 can recognize a surgical tool such as forceps, a specific living body site, bleeding, mist at the time of using the energy treatment tool 512, and the like by detecting the shape, color, and the like of an edge of the object included in the captured image. When displaying the captured image on the display device 602, the control unit 713 may superimpose various types of surgery support information on the image of the surgical site to perform display by using the recognition result. Since the surgery support information is superimposed to be displayed and presented to the operator 531, the burden on the operator 531 can be reduced and the operator 531 can reliably perform the surgery.

The transmission cable 700 connecting the camera head 502 with the CCU 601 is an electric signal cable compatible with electric signal communication, an optical fiber compatible with optical communication, or a composite cable formed by combining the electric signal cable and the optical fiber.

Here, in the illustrated example, communication is performed by wire using the transmission cable 700, but communication between the camera head 502 and the CCU 601 may be performed wirelessly.

The embodiments of the present disclosure have been described above, but these embodiments may be implemented with various modifications without departing from the gist of the present disclosure. For example, two or more embodiments may be implemented in combination.

Note that the present disclosure can also have the following configurations.

(1)

A solid-state imaging device including:
a first pixel; and
a second pixel located in a first direction of the first pixel,
in which each of the first and second pixels includes a first transistor and a second transistor, and
the first and second transistors in the second pixel are disposed periodically in the first direction with respect to the first and second transistors in the first pixel.

(2)

The solid-state imaging device according to (1), further including:
a third pixel located in a second direction of the first pixel; and
a fourth pixel located in the second direction of the second pixel,
in which each of the third and fourth pixels includes the first transistor and the second transistor, and
the first and second transistors in the fourth pixel are disposed periodically in the first direction with respect to the first and second transistors in the third pixel.

(3)

The solid-state imaging device according to (2),
in which the first and second transistors in the third pixel are disposed symmetrically in the second direction with respect to the first and second transistors in the first pixel, and/or
the first and second transistors in the fourth pixel are disposed symmetrically in the second direction with respect to the first and second transistors in the second pixel.

(4)

The solid-state imaging device according to (2),
in which the first and second transistors in the third pixel are disposed periodically in the second direction with respect to the first and second transistors in the first pixel, and/or
the first and second transistors in the fourth pixel are disposed periodically in the second direction with respect to the first and second transistors in the second pixel.

(5)

The solid-state imaging device according to (1),
in which each of the first and second pixels includes a photoelectric conversion unit provided in a substrate, and includes the first and second transistors under the substrate.

(6)

The solid-state imaging device according to (5),
in which the photoelectric conversion unit includes a first semiconductor region and a second semiconductor region surrounding the first semiconductor region, and
the first and second semiconductor regions in the second pixel are disposed periodically in the first direction with respect to the first and second semiconductor regions in the first pixel.

(7)

The solid-state imaging device according to (5),
in which each of the first and second pixels includes a floating diffusion portion in the substrate, and
the floating diffusion portion in the second pixel is disposed periodically in the first direction with respect to the floating diffusion portion in the first pixel.

(8)

The solid-state imaging device according to (5), further including a first wiring layer provided under the substrate and including a plurality of first wirings,
in which the first wirings in the second pixel are disposed periodically in the first direction with respect to the first wirings in the first pixel.

(9)

The solid-state imaging device according to (9),
in which each of the first and second pixels includes the plurality of first wirings extending to one side in the first direction or second direction.

(10)

The solid-state imaging device according to (8), further including a second wiring layer provided under the first wiring layer and including a plurality of second wirings,
in which the second wirings in the second pixel are disposed periodically in the first direction with respect to the second wirings in the first pixel.

(11)

The solid-state imaging device according to (10),
in which each of the first and second pixels includes the plurality of first wirings extending to one side in the first direction or second direction and the plurality of second wirings extending to the other side in the first direction or second direction.

(12)

The solid-state imaging device according to (1),
in which the first transistor is a transfer transistor.

(13)

The solid-state imaging device according to (12),
in which the second transistor is a pixel transistor other than the transfer transistor or a dummy transistor that is a dummy of the pixel transistor.

(14)

The solid-state imaging device according to (1),
in which at least one of the first pixel or the second pixel does not include an element isolation insulation film between the first transistor and the second transistor.

(15)

The solid-state imaging device according to (1), further including an element isolation insulation film surrounding each of the first and second pixels.

(16)

A solid-state imaging device including:
a first pixel; and
a second pixel located in a first direction of the first pixel,
in which each of the first and second pixels includes a first transistor and a second transistor, and
at least one of the first pixel or the second pixel does not include an element isolation insulation film between the first transistor and the second transistor.

(17)

The solid-state imaging device according to (16), further including an element isolation insulation film surrounding each of the first and second pixels.

(18)

A solid-state imaging device including:
a first pixel;
a second pixel located adjacent to the first pixel in a first direction;
a third pixel located adjacent to the first pixel in a second direction;
a fourth pixel located adjacent to the second pixel in the second direction;
a first element isolation insulation film provided in each of the first to fourth pixels; and
a second element isolation insulation film surrounding each of the first to fourth pixels,
in which at least one of the first element isolation insulation film or the second element isolation insulation film includes a portion having a first width and a portion having a second width larger than the first width in plan view.

(19)

The solid-state imaging device according to (18),
in which each of the first to fourth pixels includes a first transistor and a second transistor,
the first element isolation insulation film is disposed between the first transistor and the second transistor,
the first transistors in the first to fourth pixels are disposed periodically in the first and second directions, and
the second transistors in the first to fourth pixels include gate electrodes having two or more types of areas in plan view.

(20)

The solid-state imaging device according to (18),
in which each of the first to fourth pixels includes a first transistor and a second transistor,
the first element isolation insulation film is disposed between the first transistor and the second transistor,
the first transistors in the first to fourth pixels are disposed periodically in the first and second directions, and
the second transistors in the first to fourth pixels are disposed periodically in the first and the second directions.

(21)

The solid-state imaging device according to (18),
in which each of the first to fourth pixels includes a plurality of contact plugs provided under a substrate, and
the plurality of contact plugs in the first to fourth pixels are disposed periodically in the first and second directions.

(22)

A manufacturing method for a solid-state imaging device including a first pixel and a second pixel located in a first direction of the first pixel, the method including:
forming each of the first and second pixels so as to include a first transistor and a second transistor; and
disposing the first and second transistors in the second pixel periodically in the first direction with respect to the first and second transistors in the first pixel.

(23)

The manufacturing method for a solid-state imaging device according to (22), further including forming a third pixel located in a second direction of the first pixel and a fourth pixel located in the second direction of the second pixel,
in which each of the third and fourth pixels is formed so as to include the first transistor and the second transistor, and
the first and second transistors in the fourth pixel are disposed periodically in the first direction with respect to the first and second transistors in the third pixel.

(24)

The manufacturing method for a solid-state imaging device according to (22),
in which at least one of the first pixel or the second pixel is formed so as not to include an element isolation insulation film between the first transistor and the second transistor.

(25)

A solid-state imaging device including:
a first pixel;
a second pixel located in a first direction of the first pixel;
a third pixel located in a second direction of the first pixel; and
a fourth pixel located in the second direction of the second pixel,
in which each of the first to fourth pixels includes a first transistor and a second transistor,
the second transistor in the second pixel is disposed symmetrically in the first direction with respect to the second transistor in the first pixel,
the second transistor in the fourth pixel is disposed symmetrically in the first direction with respect to the second transistor in the third pixel,
the second transistor in the third pixel is disposed periodically in the second direction with respect to the second transistor in the first pixel,
the second transistor in the fourth pixel is disposed periodically in the second direction with respect to the second transistor in the second pixel, and
at least two of the first to fourth pixels include a lens common to the at least two pixels.

(26)

The solid-state imaging device according to (15), in which a side surface of the element isolation insulation film includes a portion having a tapered shape.

(27)

The solid-state imaging device according to (1), in which the first and second pixels each have a hexagonal shape in plan view.

(28)

The solid-state imaging device according to (1), in which the first or second pixel includes an element isolation insulation film provided between the first transistor and the second transistor, and located on a symmetry plane of the first or second pixel, which is perpendicular to the first direction.

(29)

The solid-state imaging device according to (5), further including:
an element isolation insulation film surrounding each of the first and second pixels; and
a plug provided under the substrate, provided at a position overlapping the element isolation insulation film in plan view, and supplying a fixed potential to the substrate.

(30)

The solid-state imaging device according to (3),
in which each of the first to fourth pixels includes a photoelectric conversion unit provided in a substrate,
the photoelectric conversion unit of each of the first to fourth pixels includes a first semiconductor region and a second semiconductor region surrounding the first semiconductor region,
the first semiconductor region in each of the first and third pixels includes a portion interposed between the first transistor in the first pixel and the first transistor in the third pixel in plan view,
the first semiconductor region in each of the second and fourth pixels includes a portion interposed between the first transistor in the second pixel and the first transistor in the fourth pixel in plan view, and
the first to fourth pixels share at least three of the second transistors in the first to fourth pixels.

(31)

A solid-state imaging device including:
a first pixel; and
a second pixel located in a first direction of the first pixel,
in which each of the first and second pixels includes a first transistor,
the first transistor in the second pixel is disposed periodically in the first direction with respect to the first transistor in the first pixel, and
the second transistor common to the first and second pixels is provided outside the first and second pixels.

(32)

The solid-state imaging device according to (31), further including:
a third pixel located in a second direction of the first pixel; and
a fourth pixel located in the second direction of the second pixel,
in which each of the third and fourth pixels includes the first transistor, and
the second transistor common to the first to fourth pixels is provided outside the first to fourth pixels.

### REFERENCE SIGNS LIST

1 Pixel
2 Pixel array region
3 Control circuit
4 Vertical drive circuit
5 Column signal processing circuit
6 Horizontal drive circuit
7 Output circuit
8 Vertical signal line
9 Horizontal signal line
11 Substrate
12 n-type semiconductor region
13 p-type semiconductor region
14 n⁺-type semiconductor region
15 Light-shielding film
16 Color filter
17 On-chip lens
21 Element isolation insulation film
22 Interlayer insulation film
23 Gate insulation film
24 Gate electrode
25 Wiring layer
25a Wiring
26 Wiring layer
26a Wiring
27 Wiring layer
28 Support substrate
29 Element isolation insulation film
29a Internal element isolation insulation film
29b External element isolation insulation film
31 Contact plug
32 Well contact region
PD Photodiode
TG Transfer transistor
RST Reset transistor
SEL Selection transistor
AMP Amplification transistor
Dummy Dummy transistor

What is claimed is:

1. A solid-state imaging device, comprising:
a first pixel; and
a second pixel located in a first direction of the first pixel,
wherein each of the first and second pixels includes a first transistor and a second transistor, and
the first and second transistors in the second pixel are disposed periodically in the first direction with respect to the first and second transistors in the first pixel.

2. The solid-state imaging device according to claim 1, further comprising:
a third pixel located in a second direction of the first pixel; and
a fourth pixel located in the second direction of the second pixel,
wherein each of the third and fourth pixels includes the first transistor and the second transistor, and
the first and second transistors in the fourth pixel are disposed periodically in the first direction with respect to the first and second transistors in the third pixel.

3. The solid-state imaging device according to claim 2,
wherein the first and second transistors in the third pixel are disposed symmetrically in the second direction with respect to the first and second transistors in the first pixel, and/or
the first and second transistors in the fourth pixel are disposed symmetrically in the second direction with respect to the first and second transistors in the second pixel.

4. The solid-state imaging device according to claim 2,
wherein the first and second transistors in the third pixel are disposed periodically in the second direction with respect to the first and second transistors in the first pixel, and/or
the first and second transistors in the fourth pixel are disposed periodically in the second direction with respect to the first and second transistors in the second pixel.

5. The solid-state imaging device according to claim 1,
wherein each of the first and second pixels includes a photoelectric conversion unit provided in a substrate, and includes the first and second transistors under the substrate.

6. The solid-state imaging device according to claim 5,
wherein the photoelectric conversion unit includes a first semiconductor region and a second semiconductor region surrounding the first semiconductor region, and
the first and second semiconductor regions in the second pixel are disposed periodically in the first direction with respect to the first and second semiconductor regions in the first pixel.

7. The solid-state imaging device according to claim 5,
wherein each of the first and second pixels includes a floating diffusion portion in the substrate, and
the floating diffusion portion in the second pixel is disposed periodically in the first direction with respect to the floating diffusion portion in the first pixel.

8. The solid-state imaging device according to claim 5, further comprising a first wiring layer provided under the substrate and including a plurality of first wirings,
wherein the first wirings in the second pixel are disposed periodically in the first direction with respect to the first wirings in the first pixel.

9. The solid-state imaging device according to claim 8,
wherein each of the first and second pixels includes the plurality of first wirings extending to one side in the first direction or second direction.

10. The solid-state imaging device according to claim 8, further comprising a second wiring layer provided under the first wiring layer and including a plurality of second wirings,
wherein the second wirings in the second pixel are disposed periodically in the first direction with respect to the second wirings in the first pixel.

11. The solid-state imaging device according to claim 10,
wherein each of the first and second pixels includes the plurality of first wirings extending to one side in the first direction or second direction and the plurality of second wirings extending to the other side in the first direction or second direction.

12. The solid-state imaging device according to claim 1,
wherein the first transistor is a transfer transistor.

13. The solid-state imaging device according to claim 12,
wherein the second transistor is a pixel transistor other than the transfer transistor or a dummy transistor that is a dummy of the pixel transistor.

14. The solid-state imaging device according to claim 1,
wherein at least one of the first pixel or the second pixel does not include an element isolation insulation film between the first transistor and the second transistor.

15. The solid-state imaging device according to claim 1, further comprising an element isolation insulation film surrounding each of the first and second pixels.

16. A solid-state imaging device, comprising:
a first pixel; and
a second pixel located in a first direction of the first pixel,
wherein each of the first and second pixels includes a first transistor and a second transistor, and
at least one of the first pixel or the second pixel does not include an element isolation insulation film between the first transistor and the second transistor.

17. The solid-state imaging device according to claim 16, further comprising an element isolation insulation film surrounding each of the first and second pixels.

18. A solid-state imaging device, comprising:
a first pixel;
a second pixel located adjacent to the first pixel in a first direction;
a third pixel located adjacent to the first pixel in a second direction;
a fourth pixel located adjacent to the second pixel in the second direction;
a first element isolation insulation film provided in each of the first to fourth pixels; and
a second element isolation insulation film surrounding each of the first to fourth pixels,
wherein at least one of the first element isolation insulation film or the second element isolation insulation film includes a portion having a first width and a portion having a second width larger than the first width in plan view.

19. The solid-state imaging device according to claim 18,
wherein each of the first to fourth pixels includes a first transistor and a second transistor,
the first element isolation insulation film is disposed between the first transistor and the second transistor,
the first transistors in the first to fourth pixels are disposed periodically in the first and second directions, and
the second transistors in the first to fourth pixels include gate electrodes having two or more types of areas in plan view.

20. The solid-state imaging device according to claim 18,
wherein each of the first to fourth pixels includes a first transistor and a second transistor,
the first element isolation insulation film is disposed between the first transistor and the second transistor,
the first transistors in the first to fourth pixels are disposed periodically in the first and second directions, and
the second transistors in the first to fourth pixels are disposed periodically in the first and the second directions.
